(19) United States
(12) Patent Application Publication
(10) Pub. No.: US 2024/0063356 A1
(43) Pub. Date: Feb. 22, 2024

(54) DISPLAY DEVICE

(71) Applicant: Samsung Display Co., LTD., Yongin-si (KR)

(72) Inventors: Yun Yong NAM, Yongin-si (KR); So Young KOO, Yongin-si (KR); Eok Su KIM, Yongin-si (KR); Hyoung Do KIM, Yongin-si (KR); Hyung Jun KIM, Yongin-si (KR); Joon Seok PARK, Yongin-si (KR)

(21) Appl. No.: 18/342,567

(22) Filed: Jun. 27, 2023

(30) Foreign Application Priority Data
Aug. 18, 2022 (KR) 10-2022-0103165

(51) Int. Cl. H01L 33/62; H01L 25/16

(52) U.S. Cl. CPC H01L 33/62; H01L 25/167

(57) ABSTRACT

A display device includes: a first electrode and a second electrode spaced from the first electrode; a first insulating layer on the first electrode and the second electrode; a plurality of light emitting elements on the first insulating layer and on the first electrode and the second electrode; a first connection electrode on the first electrode and contacting the plurality of light emitting elements; and a second connection electrode on the second electrode and contacting the plurality of light emitting elements, wherein each of the first electrode and the second electrode includes a first metal layer and a second metal layer on the first metal layer and including a different material from the first metal layer, a thickness of the first metal layer is between 100 Å to 300 Å, and a thickness of each of the first electrode and the second electrode is 2600 Å or less.

### CROSS-REFERENCE TO RELATED APPLICATION

This application claims priority to and the benefit of Korean Patent Application No. 10-2022-0103165 filed on Aug. 18, 2022 in the Korean Intellectual Property Office, the entire content of which is incorporated by reference herein.

### BACKGROUND

### 1. Field

The present disclosure relates to a display device.

### 2. Description of the Related Art

Display devices are becoming increasingly important with the development of multimedia. Accordingly, various types of display devices such as organic light emitting displays (OLEDs) and liquid crystal displays (LCDs) are being used.

As a device for displaying an image of a display device, there is a self-luminous display device including a light emitting element. The self-luminous display device may be an organic light emitting display using an organic material as a light emitting material as a light emitting element or an inorganic light emitting display using an inorganic material as a light emitting material.

### SUMMARY

Aspects and features of embodiments of the present disclosure provide a display device capable of preventing thin-film defects that occur in an insulating layer disposed on an electrode.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, a display device including: a first electrode and a second electrode spaced from the first electrode, a first insulating layer on the first electrode and the second electrode, a plurality of light emitting elements on the first insulating layer and on the first electrode and the second electrode, a first connection electrode on the first electrode and contacting the plurality of light emitting elements, and a second connection electrode on the second electrode and contacting the plurality of light emitting elements, wherein each of the first electrode and the second electrode includes a first metal layer and a second metal layer on the first metal layer and including a different material from the first metal layer, a thickness of the first metal layer is between 100 Å to 300 Å, and a thickness of each of the first electrode and the second electrode is 2600 Å or less.

The first electrode and the second electrode may have a taper angle of 25 degrees or less.

The first metal layer and the second metal layer may have a same taper angle.

A taper angle of the first metal layer may be greater than a taper angle of the second metal layer.

The first metal layer includes molybdenum (Mo), and the second metal layer may include an alloy including aluminum (Al), nickel (Ni) and lanthanum (La).

A width of the first metal layer may be greater than a width of the second metal layer, and an end of a lower surface of the second metal layer may be recessed inward from an end of an upper surface of the first metal layer.

The display device may further include a second insulating layer on the plurality of light emitting elements, wherein the first connection electrode and the second connection electrode may be on the second insulating layer.

The first connection electrode and the second connection electrode may contact side surfaces of a portion of the second insulating layer on the plurality of light emitting elements.

The display device may further include a third insulating layer on the second insulating layer and the second connection electrode, wherein the first connection electrode may be on the third insulating layer.

The display device may further include a first wall overlapping the first electrode and a second wall overlapping the second electrode, and a bank layer around an area of the display device in which the plurality of light emitting elements are located, wherein the plurality of light emitting elements may be between the first wall and the second wall.

The first electrode may be on the first wall, and the second electrode may be on the second wall.

Each of the first wall and the second wall may be on the first insulating layer, the first connection electrode may be on the first wall, and the second connection electrode may be on the second wall.

The display device may include a first conductive layer including a bottom metal layer, a first voltage wiring and a second voltage wiring on a substrate on which the first electrode and the second electrode are located, a buffer layer on the first conductive layer, a first active layer and a second active layer on the buffer layer, a first gate insulating layer on the first active layer and the second active layer, a second conductive layer on the first gate insulating layer and including a first gate electrode overlapping the first active layer and a second gate electrode overlapping the second active layer, a first interlayer insulating layer on the second conductive layer, a third conductive layer on the first interlayer insulating layer and including a first conductive pattern contacting the bottom metal layer and the first active layer, a second conductive pattern contacting the second voltage wiring and a third conductive pattern contacting the first active layer and the first voltage wiring, and a via layer on the third conductive layer, wherein the first electrode is on the via layer to contact the first conductive pattern, and the second electrode is on the via layer to contact the second conductive pattern.

The display device may include a first conductive layer including a bottom metal layer, a first voltage wiring, and a second voltage wiring on a substrate on which the first electrode and the second electrode are located, a buffer layer on the first conductive layer, a first active layer and a second active layer on the buffer layer, a first gate insulating layer on the first active layer and the second active layer, a second conductive layer on the first gate insulating layer and including a first gate electrode overlapping the first active layer and a second gate electrode overlapping the second active layer, a first interlayer insulating layer on the second conductive layer; and a via layer on the first interlayer insulating layer, wherein the first electrode may be on the via layer to contact the first active layer and the bottom metal layer, and the second electrode may be on the via layer to contact the second voltage wiring.

According to one or more embodiments of the present disclosure, a display device including: a first electrode and a second electrode spaced from the first electrode, a first wall overlapping the first electrode and a second wall overlapping the second electrode, a first insulating layer on the first electrode and the second electrode, a plurality of light emitting elements on the first insulating layer and on the first electrode and the second electrode, the plurality of light emitting elements being between the first wall and the second wall, a first connection electrode on the first electrode and contacting the plurality of light emitting elements, and a second connection electrode on the second electrode and contacting the plurality of light emitting elements, wherein each of the first electrode and the second electrode includes a first metal layer and a second metal layer on the first metal layer and including a different material from the first metal layer, and the first electrode and the second electrode have a taper angle of 25 degrees or less.

The first metal layer and the second metal layer may have a same taper angle.

A taper angle of the first metal layer may be greater than a taper angle of the second metal layer.

A thickness of the first metal layer may be between 100 Å to 300 Å, and a thickness of each of the first electrode and the second electrode may be 2600 Å or less.

The first metal layer may include molybdenum (Mo), and the second metal layer includes an alloy including aluminum (Al), nickel (Ni) and lanthanum (La).

The display device may further include a second insulating layer on the plurality of light emitting elements, and a third insulating layer on the second insulating layer and the second connection electrode, wherein the first connection electrode may be on the third insulating layer.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a display device according to one or more embodiments;

FIG. 2 is a plan view illustrating the arrangement of a plurality of wirings included in the display device according to one or more embodiments;

FIG. 3 is an equivalent circuit diagram of a subpixel of the display device according to one or more embodiments;

FIG. 4 is a plan view of a pixel of the display device according to one or more embodiments;

FIG. 5 is a cross-sectional view taken along the line E1-E1′ of FIG. 4;

FIG. 6 is a cross-sectional view taken along the line E2-E2′ of FIG. 4;

FIG. 7 is an enlarged view of a portion A of FIG. 5;

FIG. 8 is a schematic cutaway view of a light emitting element according to one or more embodiments;

FIGS. 9 through 12 are cross-sectional views schematically illustrating a process of forming electrodes of the display device according to one or more embodiments;

FIG. 13 is a graph illustrating a taper angle with respect to the thickness of each layer of electrodes according to one or more embodiments;

FIGS. 14A through 14D are photomicrographs showing a taper angle according to the thickness of an electrode according to one or more embodiments;

FIGS. 15A through 15D are photomicrographs showing a taper angle according to the thickness of a first metal layer of an electrode according to one or more embodiments;

FIGS. 16 and 17 are cross-sectional views illustrating an end of an electrode in display devices according to one or more embodiments;

FIGS. 18 and 19 are cross-sectional views of display devices according to one or more embodiments; and

FIGS. 20 and 21 are cross-sectional views of a display device according to one or more embodiments.

### DETAILED DESCRIPTION

The present disclosure will now be described more fully hereinafter with reference to the accompanying drawings, in which embodiments of the present disclosure are shown. This disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Hereinafter, embodiments will be described with reference to the accompanying drawings.

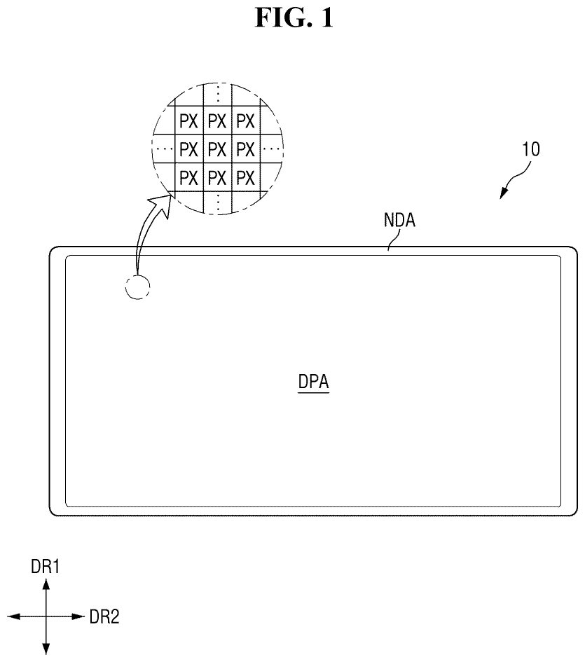

FIG. 1 is a schematic plan view of a display device 10 according to one or more embodiments.

Referring to FIG. 1, the display device 10 displays moving images or still images. The display device 10 may refer to any electronic device that provides a display screen. Examples of the display device 10 may include televisions, notebook computers, monitors, billboards, Internet of things (IoT) devices, mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras and camcorders, all of which provide a display screen.

The display device 10 includes a display panel that provides a display screen. Examples of the display panel may include inorganic light emitting diode display panels, organic light emitting display panels, quantum dot light emitting display panels, plasma display panels, and field emission display panels. A case where an inorganic light emitting diode display panel is applied as an example of the display panel will be described below, but the present disclosure is not limited to this case, and other display panels can also be applied as long as the same technical spirit is applicable.

The shape of the display device 10 can be variously modified. For example, the display device 10 may have various shapes such as a horizontally long rectangle, a vertically long rectangle, a square, a quadrilateral with rounded corners (vertices), other polygons, or a circle. The shape of a display area DPA of the display device 10 may also be similar to the overall shape of the display device 10. In FIG. 1, the display device 10 shaped like a rectangle that is long in a second direction DR2 is illustrated.

The display device 10 may include the display area DPA and a non-display area NDA along an edge or periphery of the display area DPA. The display area DPA is an area where an image can be displayed, and the non-display area NDA is an area where no image is displayed. The display area DPA may also be referred to as an active area, and the non-display area NDA may also be referred to as an inactive area. The display area DPA may generally occupy the center (or the central region) of the display device 10.

The display area DPA may include a plurality of pixels PX. The pixels PX may be arranged in a matrix direction. For example, the pixels PX may be arranged along the rows and columns of a matrix. Each of the pixels PX may be rectangular or square in a plan view. However, the present disclosure is not limited thereto, and each of the pixels PX may also have a rhombus shape having each side inclined with respect to a direction. The pixels PX may be arranged in a stripe type or an island type. In addition, each of the pixels PX may include one or more light emitting elements that emit light of a specific wavelength band to display a specific color. The non-display area NDA may be disposed around the display area DPA.

The non-display area NDA may entirely or partially surround the display area DPA. The display area DPA may be rectangular, and the non-display area NDA may be disposed adjacent to four sides of the display area DPA. The non-display area NDA may form a bezel of the display device 10. Wirings or circuit drivers included in the display device 10 may be located, or external devices may be mounted, in each non-display area NDA.

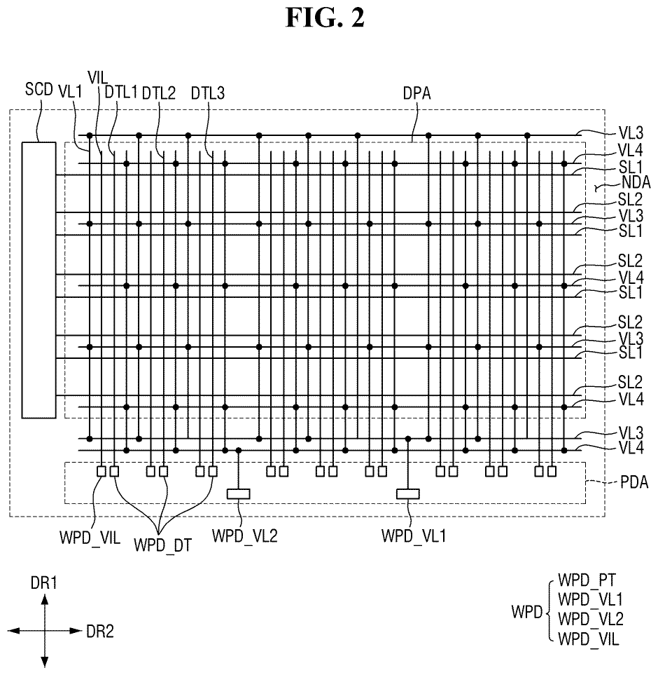

FIG. 2 is a plan view illustrating the arrangement of a plurality of wirings included in the display device 10 according to one or more embodiments.

Referring to FIG. 2, the display device 10 may include a plurality of wirings. The display device 10 may include a plurality of scan lines SL1 and SL2, a plurality of data lines DTL1 through DTL3, initialization voltage wirings VIL, and a plurality of voltage wirings VL (VL1 through VL4). In addition, in one or more embodiments, other wirings may be further disposed in the display device 10. The wirings may include wirings made of a first conductive layer and extending in a first direction DR1 and wirings made of a third conductive layer and extending in the second direction DR2. However, the directions in which the wirings extend are not limited thereto.

First scan lines SL1 and second scan lines SL2 may extend in the second direction DR2. A first scan line SL1 and a second scan line SL2 in each pair may be disposed adjacent to each other and may be spaced from other first scan lines SL1 and other second scan lines SL2 in the first direction DR1. The first scan line SL1 and the second scan line SL2 in each pair may be connected to a scan driver SCD. The first scan lines SL1 and the second scan lines SL2 may extend from the scan driver SCD in the non-display area NDA to the display area DPA.

In the present disclosure, the term “connect” may mean that any one member and another member are connected to each other not only through physical contact but also through another member (e.g., electrically connected). In addition, it can be understood that any one part and another part are connected to each other as one integrated member. Further, the connection between any one member and another member can be interpreted to include electrical connection through another member in addition to connection through direct contact.

The data lines DTL may extend in the first direction DR1. The data lines DTL include first data lines DTL1, second data lines DTL2, and third data lines DTL3. One each of the first through third data lines DTL1 through DTL3 form one set and are disposed adjacent to each other. Each of the data lines DTL1 through DTL3 may extend from the pad area PDA disposed in the non-display area NDA to the display area DPA. However, the present disclosure is not limited thereto, and the data lines DTL may also be disposed at equal intervals between a first voltage wiring VL1 and a second voltage wiring VL2 in each pair that will be described later.

The initialization voltage wirings VIL may extend in the first direction DR1. Each of the initialization voltage wirings VIL may be disposed between the data lines DTL. The initialization voltage wirings VIL may extend from the pad area PDA disposed in the non-display area NDA to the display area DPA.

First voltage wirings VL1 and second voltage wirings VL2 extend in the first direction DR1, and third voltage wirings VL3 and fourth voltage wirings VL4 extend in the second direction DR2. The first voltage wirings VL1 and the second voltage wirings VL2 may be alternately arranged along the second direction DR2, and the third voltage wirings VL3 and the fourth voltage wirings VL4 may be alternately arranged along the first direction DR1. The first voltage wirings VL1 and the second voltage wirings VL2 may extend in the first direction DR1 to cross the display area DPA. Among the third voltage wirings VL3 and the fourth voltage wirings VL4, some wirings may be disposed in the display area DPA, and other wirings may be disposed in the non-display area NDA located on both sides of the display area DPA in the first direction DR1. The first voltage wirings VL1 and the second voltage wirings VL2 may be formed of a conductive layer disposed on a different layer from the third voltage wirings VL3 and the fourth voltage wirings VL4. Each of the first voltage wirings VL1 may be connected to at least one third voltage wiring VL3, and each of the second voltage wirings VL2 may be connected to at least one fourth voltage wiring VL4. The voltage wirings VL may have a mesh structure in the entire display area DPA. However, the present disclosure is not limited thereto.

The data lines DTL, the initialization voltage wirings VIL, the first voltage wirings VL1, and the second voltage wirings VL2 may be electrically connected to at least one wiring pad WPD. Each wiring pad WPD may be disposed in the non-display area NDA. In one or more embodiments, each wiring pad WPD may be disposed in the pad area PDA located on a lower side of the display area DPA, which is a second side in the first direction DR1. Each pair of the first and second scan lines SL1 and SL2 are connected to the scan driver SCD disposed in the non-display area NDA, and the data lines DTL are connected to different data wiring pads WPD_DT. Each of the initialization voltage wirings VIL is connected to an initialization wiring pad WPD_VIL, the first voltage wirings VL1 are connected to a first voltage wiring pad WPD_VL1, and the second voltage wirings VL2 are connected to a second voltage wiring pad WPD_VL2. An external device may be mounted on the wiring pads WPD. The external device may be mounted on the wiring pads WPD through an anisotropic conductive film, ultrasonic bonding, or the like. Although each wiring pad WPD is disposed in the pad area PDA located on the lower side of the display area DPA in the drawing, the present disclosure is not limited thereto. Some of the wiring pads WPD may also be disposed in an area located on an upper side or any one of left and right sides of the display area DPA.

Each pixel PX or subpixel SPXn (where n is an integer of 1 to 3) of the display device 10 includes a pixel driving circuit. The above-described wirings may transmit a driving signal to each pixel driving circuit while passing through or around each pixel PX. The pixel driving circuit may include a transistor and a capacitor. The number of transistors and capacitors in each pixel driving circuit can be variously changed. According to one or more embodiments, each subpixel SPXn of the display device 10 may have a 3T1C structure in which the pixel driving circuit includes three transistors and one capacitor. Although the pixel driving circuit will be described below using the 3T1C structure as an example, the present disclosure is not limited thereto, and other various modified structures such as a 2T1C structure, a 7T1C structure, and a 6T1C structure are also applicable.

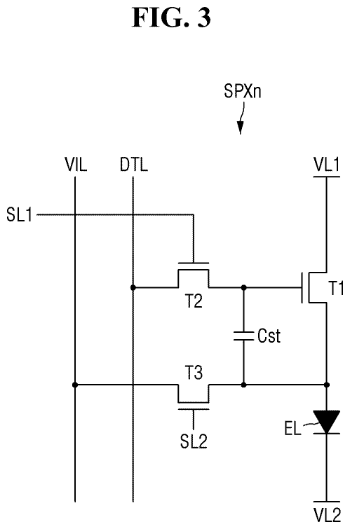

FIG. 3 is a pixel circuit diagram of a subpixel SPXn disposed in the display device 10 according to one or more embodiments.

Referring to FIG. 3, each subpixel SPXn of the display device 10 according to one or more embodiments includes three transistors T1 through T3 and one storage capacitor Cst in addition to a light emitting diode EL.

The light emitting diode EL emits light according to a current supplied through a first transistor T1. The light emitting diode EL includes a first electrode, a second electrode, and at least one light emitting element disposed between them. The light emitting element may emit light of a specific wavelength band in response to electrical signals received from the first electrode and the second electrode.

A first end of the light emitting diode EL may be connected to a source electrode of the first transistor T1, and a second end of the light emitting diode EL may be connected to a second voltage wiring VL2 to which a low potential voltage (hereinafter, referred to as a second power supply voltage) lower than a high potential voltage (hereinafter, referred to as a first power supply voltage) of a first voltage wiring VL1 is supplied.

The first transistor T1 adjusts a current flowing from the first voltage wiring VL1, to which the first power supply voltage is supplied, to the light emitting diode EL according to a voltage difference between a gate electrode and the source electrode of the first transistor T1. For example, the first transistor T1 may be a driving transistor for driving the light emitting diode EL. The first transistor T1 may have the gate electrode connected to a source electrode of a second transistor T2, the source electrode connected to the first electrode of the light emitting diode EL, and a drain electrode connected to the first voltage wiring VL1 to which the first power supply voltage is applied.

The second transistor T2 is turned on by a scan signal of a first scan line SL1 to connect a data line DTL to the gate electrode of the first transistor T1. The second transistor T2 may have a gate electrode connected to the first scan line SL1, the source electrode connected to the gate electrode of the first transistor T1, and a drain electrode connected to the data line DTL.

A third transistor T3 is turned on by a scan signal of a second scan line SL2 to connect an initialization voltage wiring VIL to the first end of the light emitting diode EL. The third transistor T3 may have a gate electrode connected to the second scan line SL2, a drain electrode connected to the initialization voltage wiring VIL, and a source electrode connected to the first end of the light emitting diode EL or the source electrode of the first transistor T1.

In one or more embodiments, the source electrode and the drain electrode of each of the transistors T1 through T3 are not limited to the above description, and the opposite may also be the case. In addition, each of the transistors T1 through T3 may be formed as a thin-film transistor (TFT). In addition, although each of the transistors T1 through T3 is mainly described as an N-type metal oxide semiconductor field effect transistor (MOSFET) in FIG. 3, the present disclosure is not limited thereto. That is, each of the transistors T1 through T3 may also be formed as a P-type MOSFET, or some of the transistors T1 through T3 may be formed as N-type MOSFETs, and the other may be formed as a P-type MOSFET.

The storage capacitor Cst is formed between the gate electrode and the source electrode of the first transistor T1. The storage capacitor Cst stores a difference between a gate voltage and a source voltage of the first transistor T1.

In the embodiment of FIG. 3, the gate electrode of the second transistor T2 may be connected to the first scan line SL1, and the gate electrode of the third transistor T3 may be connected to the second scan line SL2. The first scan line SL1 and the second scan line SL2 may be different scan lines, and the second transistor T2 and the third transistor T3 may be turned on by scan signals transmitted from the different scan lines. However, the present disclosure is not limited thereto.

In one or more embodiments, the gate electrodes of the second transistor T2 and the third transistor T3 may be connected to the same scan line SL. The second transistor T2 and the third transistor T3 may be concurrently (e.g., simultaneously) turned on by a scan signal transmitted from the same scan line.

The structure of a pixel PX of the display device 10 according to one or more embodiments will now be described in detail with further reference to other drawings.

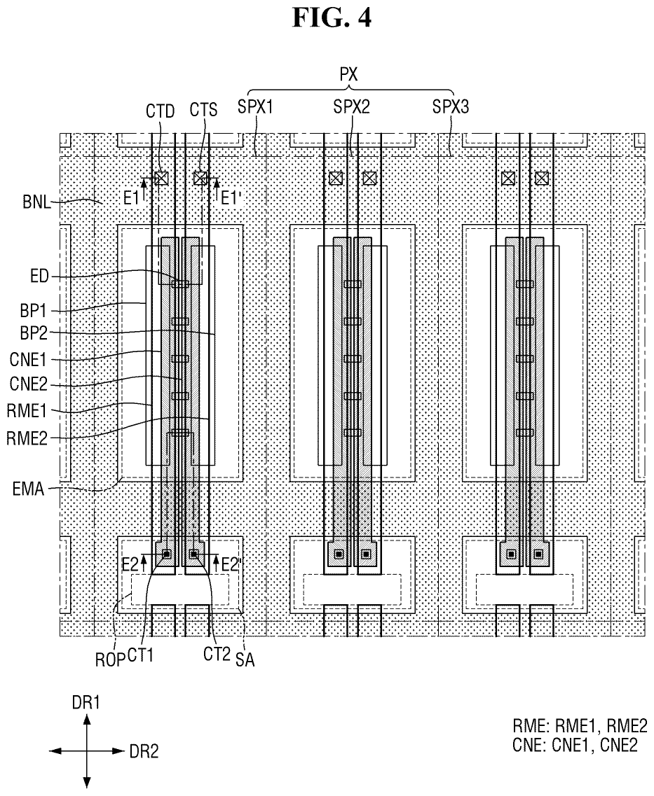

FIG. 4 is a plan view of a pixel PX of the display device 10 according to one or more embodiments.

FIG. 4 illustrates the planar arrangement of electrodes RME (RME1 and RME2), walls BP1 and BP2, a bank layer BNL, a plurality of light emitting elements ED, and connection electrodes CNE (CNE1 and CNE2) disposed in one pixel PX of the display device 10.

Referring to FIG. 4, each of the pixels PX of the display device 10 may include a plurality of subpixels SPXn. For example, one pixel PX may include a first subpixel SPX1, a second subpixel SPX2, and a third subpixel SPX3. The first subpixel SPX1 may emit light of a first color, the second subpixel SPX2 may emit light of a second color, and the third subpixel SPX3 may emit light of a third color. For example, the first color may be blue, the second color may be green, and the third color may be red. However, the present disclosure is not limited thereto, and the subpixels SPXn may also emit light of the same color. In one or more embodiments, the subpixels SPXn may emit blue light. Although one pixel PX includes three subpixels SPXn in the drawing, the present disclosure is not limited thereto, and the pixel PX may also include a greater number of subpixels SPXn.

Each subpixel SPXn of the display device 10 may include an emission area EMA and a non-emission area. The emission area EMA may be an area in which the light emitting elements ED are disposed to emit light of a specific wavelength band. The non-emission area may be an area in which the light emitting elements ED are not disposed and from which no light is output because light emitted from the light emitting elements ED does not reach this area.

The emission area EMA may include an area in which the light emitting elements ED are disposed and an area which is adjacent to the light emitting elements ED and from that light emitted from the light emitting elements ED is output. For example, the emission area EMA may also include an area from which light emitted from the light emitting elements ED is output after being reflected or refracted by other members. A plurality of light emitting elements ED may be disposed in each subpixel SPXn, and an area where the light emitting elements ED are disposed and an area adjacent to this area may form the emission area EMA.

Although the respective emission areas EMA of the subpixels SPXn have the same area in the drawing, the present disclosure is not limited thereto. In one or more embodiments, the emission area EMA of each subpixel SPXn may have a different area according to the color or wavelength band of light emitted from the light emitting elements ED disposed in the subpixel SPXn.

Each subpixel SPXn may further include a sub-area SA disposed in the non-emission area. The sub-area SA of a corresponding subpixel SPXn may be disposed on a lower side of the emission area EMA which is the second side in the first direction DR1. The emission area EMA and the sub-area SA may be alternately arranged along the first direction DR1, and the sub-area SA may be disposed between the emission areas EMA of different subpixels SPXn spaced from each other in the first direction DR1. For example, the emission area EMA and the sub-area SA may be alternately arranged along the first direction DR1 and may each be repeatedly arranged along the second direction DR2. However, the present disclosure is not limited thereto, and the arrangement of the emission areas EMA and the sub-areas SA in a plurality of pixels PX may also be different from that in FIG. 4.

Light may not exit from the sub-area SA because the light emitting elements ED are not disposed in the sub-area SA, but a portion of each of the electrodes RME disposed in each subpixel SPXn may be disposed in the sub-area SA. The electrodes RME disposed in different subpixels SPXn may be separated from each other in a separation portion ROP of the sub-area SA.

The display device 10 according to one or more embodiments may include the electrodes RME (RME1 and RME2), the walls BP1 and BP2, the bank layer BNL, the light emitting elements ED, and the connection electrodes CNE (CNE1 and CNE2).

The walls BP1 and BP2 may be disposed in the emission area EMA of each subpixel SPXn. The walls BP1 and BP2 may extend in the first direction DR1 and may be spaced from each other in the second direction DR2.

For example, the walls BP1 and BP2 may include a first wall BP1 and a second wall BP2 spaced from each other in the second direction DR2 in the emission area EMA of each subpixel SPXn. The first wall BP1 may be disposed on a left side of a center of the emission area EMA which is a first side in the second direction DR2, and the second wall BP2 may be spaced from the first wall BP1 and disposed on a right side of the center of the emission area EMA which is a second side in the second direction DR2. The first wall BP1 and the second wall BP2 may be alternately arranged along the second direction DR2 and may be disposed as island-shaped patterns in the display area DPA. A plurality of light emitting elements ED may be disposed between the first wall BP1 and the second wall BP2.

The first wall BP1 and the second wall BP2 may have the same length in the first direction DR1 but may be shorter than the emission area EMA surrounded by the bank layer BNL in the first direction DR1. The first wall BP1 and the second wall BP2 may be spaced from portions of the bank layer BNL that extend in the second direction DR2. In one or more embodiments, the length of each of the walls BP1 and BP2 in the first direction DR1 may be smaller than the length of the emission area EMA surrounded by the bank layer BNL in the first direction DR1. However, the present disclosure is not limited thereto, and the walls BP1 and BP2 may also be integrated with the bank layer BNL or may partially overlap the portions of the bank layer BNL that extend in the second direction DR2. In this case, the length of each of the walls BP1 and BP2 in the first direction DR1 may be equal to or greater than the length of the emission area EMA surrounded by the bank layer BNL in the first direction DR1.

Although two walls BP1 and BP2 are disposed in each subpixel SPXn in the drawing, the present disclosure is not limited thereto. The number and shape of the walls BP1 and BP2 may vary according to the number or arrangement structure of the electrodes RME.

The electrodes RME (RME1 and RME2) extend in one direction and are disposed in each subpixel SPXn. The electrodes RME1 and RME2 may extend in the first direction DR1 to lie in the emission area EMA and the sub-area SA of each subpixel SPXn and may be spaced from each other in the second direction DR2. The electrodes RME may be electrically connected to the light emitting elements ED to be described later. However, the present disclosure is not limited thereto, and the electrodes RME may also not be electrically connected to the light emitting elements ED.

The display device 10 may include a first electrode RME1 and a second electrode RME2 disposed in each subpixel SPXn. The first electrode RME1 is disposed on the left side of the center of the emission area EMA, and the second electrode RME2 is spaced from the first electrode RME1 in the second direction DR2 and disposed on the right side of the center of the emission area EMA. The first electrode RME1 may be disposed on the first wall BP1, and the second electrode RME2 may be disposed on the second wall BP2. The first electrode RME1 and the second electrode RME2 may extend beyond the bank layer BNL to lie in a corresponding subpixel SPXn and a portion of the sub-area SA. The first electrodes RME1 and the second electrodes RME2 of different subpixels SPXn may be spaced or separated from each other by the separation portion ROP located in the sub-area SA of any one subpixel SPXn.

Although two electrodes RME extend in the first direction DR1 in each subpixel SPXn in the drawing, the present disclosure is not limited thereto. For example, in the display device 10, a greater number of the electrodes RME may be disposed in one subpixel SPXn, or the electrodes RME may be partially bent and may have a different width according to position.

The bank layer BNL may be around (e.g., may surround) the subpixels SPXn, the emission areas EMA, and the sub-areas SA. The bank layer BNL may be disposed at boundaries between the subpixels SPXn adjacent to each other in the first direction DR1 and the second direction DR2 and also may be disposed at boundaries between the emission areas EMA and the sub-areas SA. The subpixels SPXn, the emission areas EMA and the sub-areas SA of the display device 10 may be areas separated by the bank layer BNL. Distances between the subpixels SPXn, the emission areas EMA, and the sub-areas SA may vary according to a width of the bank layer BNL.

The bank layer BNL may include portions extending in the first direction DR1 and the second direction DR2 in a plan view to form a grid pattern in the entire display area DPA. The bank layer BNL may be disposed at the boundary of each subpixel SPXn to separate neighboring subpixels SPXn. In addition, the bank layer BNL may be around (e.g., may surround) the emission area EMA and the sub-area SA disposed in each subpixel SPXn to separate them from each other.

The light emitting elements ED may be disposed in the emission area EMA. The light emitting elements ED may be disposed between the walls BP1 and BP2 and may be spaced from each other in the first direction DR1. In one or more embodiments, the light emitting elements ED may extend in a direction, and both ends thereof may be disposed on different electrodes RME, respectively. A length of each light emitting element ED may be greater than a distance between the electrodes RME spaced in the second direction DR2. The direction in which the light emitting elements ED extend may be substantially perpendicular to the first direction DR1 in which the electrodes RME extend. However, the present disclosure is not limited thereto, and the direction in which the light emitting elements ED extend may also be the second direction DR2 or a direction oblique to the second direction DR2.

The connection electrodes CNE (CNE1 and CNE2) may be disposed on the electrodes RME and the walls BP1 and BP2. The connection electrodes CNE may extend in a direction and may be spaced from each other. Each of the connection electrodes CNE may contact the light emitting elements ED and may be electrically connected to an electrode RME or a conductive layer under the electrode RME.

The connection electrodes CNE may include a first connection electrode CNE1 and a second connection electrode CNE2 disposed in each subpixel SPXn. The first connection electrode CNE1 may extend in the first direction DR1 and may be disposed on the first electrode RME1 or the first wall BP1. The first connection electrode CNE1 may partially overlap the first electrode RME1 and may extend from the emission area EMA to the sub-area SA beyond the bank layer BNL. The second connection electrode CNE2 may extend in the first direction DR1 and may be disposed on the second electrode RME2 or the second wall BP2. The second connection electrode CNE2 may partially overlap the second electrode RME2 and may extend from the emission area EMA to the sub-area SA beyond the bank layer BNL.

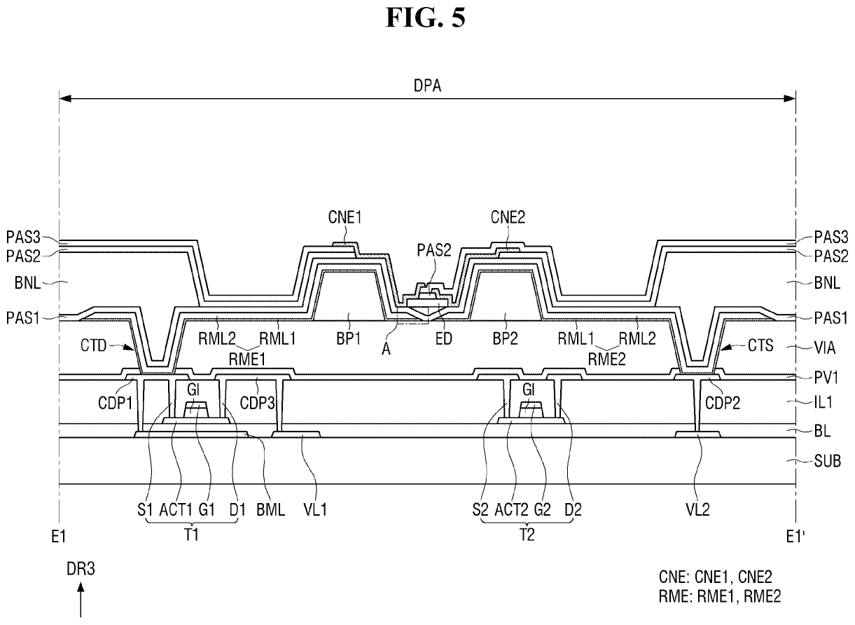

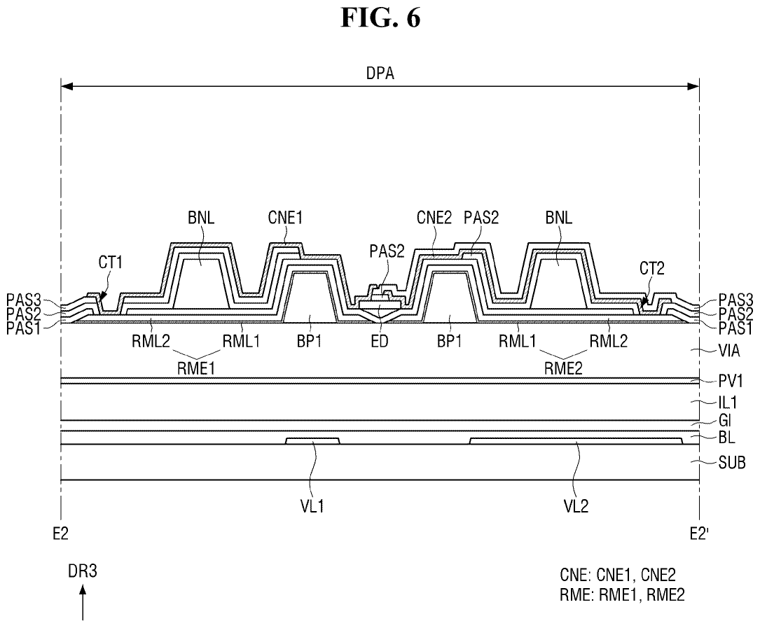

FIG. 5 is a cross-sectional view taken along the line E1-E1′ of FIG. 4. FIG. 6 is a cross-sectional view taken along the line E2-E2′ of FIG. 4.

FIG. 5 illustrates a cross section across both ends of a light emitting element ED and electrode contact holes CTD and CTS disposed in the first subpixel SPX1. FIG. 6 illustrates a cross section across both ends of a light emitting element ED and contact portions CT1 and CT2 disposed in the first subpixel SPX1.

Referring to FIGS. 5 and 6 in connection with FIG. 4, in the cross-sectional structure of the display device 10, the display device 10 may include a first substrate SUB and a semiconductor layer, a plurality of conductive layers and a plurality of insulating layers disposed on the first substrate SUB. In addition, the display device 10 may include the electrodes RME (RME1 and RME2), the light emitting elements ED, and the connection electrodes CNE (CNE1 and CNE2).

The first substrate SUB may be an insulating substrate. The first substrate SUB may be made of an insulating material such as glass, quartz, or polymer resin. In addition, the first substrate SUB may be a rigid substrate, but may also be a flexible substrate that can be bent, folded, rolled, etc. The first substrate SUB may include the display area DPA and the non-display area NDA around (e.g., surrounding) the display area DPA, and the display area DPA may include the emission area EMA and the sub-area SA that is a part of the non-emission area.

A first conductive layer may include a bottom metal layer BML, a first voltage wiring VL1, and a second voltage wiring VL2. The bottom metal layer BML is overlapped by a first active layer ACT1 of a first transistor T1 in a thickness direction of the substrate SUB (e.g., a third direction DR3). The bottom metal layer BML may prevent light from entering the first active layer ACT1 of the first transistor T1 or may be electrically connected to the first active layer ACT1 to stabilize electrical characteristics of the first transistor T1. However, the bottom metal layer BML may also be omitted.

A high potential voltage (or a first power supply voltage) supplied to the first electrode RME1 may be applied to the first voltage wiring VL1, and a low potential voltage (or a second power supply voltage) supplied to the second electrode RME2 may be applied to the second voltage wiring VL2. The first voltage wiring VL1 may be electrically connected to the first transistor T1 through a conductive pattern (e.g., a third conductive pattern CDP3) of the third conductive layer. The second voltage wiring VL2 may be electrically connected to the second electrode RME2 through a conductive pattern (e.g., a second conductive pattern CDP2) of the third conductive layer.

Although the first voltage wiring VL1 and the second voltage wiring VL2 are disposed in the first conductive layer in the drawings (e.g., see FIG. 5), the present disclosure is not limited thereto. In one or more embodiments, the first voltage wiring VL1 and the second voltage wiring VL2 may be disposed in a third conductive layer and directly electrically connected to the first transistor T1 and the second electrode RME2, respectively.

A buffer layer BL may be disposed on the first conductive layer and the first substrate SUB. The buffer layer BL may be formed on the first substrate SUB to protect transistors of the pixel PX from moisture introduced through the first substrate SUB which is vulnerable to moisture penetration and may perform a surface planarization function.

The semiconductor layer is disposed on the buffer layer BL. The semiconductor layer may include the first active layer ACT1 of the first transistor T1 and a second active layer ACT2 of a second transistor T2. The first active layer ACT1 and the second active layer ACT2 may respectively be partially overlapped by a first gate electrode G1 and a second gate electrode G2 of a second conductive layer which will be described later in the third direction DR3. The first gate electrode G1 and the second gate electrode G2 of the second conductive layer will be described later.

The semiconductor layer may include polycrystalline silicon, monocrystalline silicon, an oxide semiconductor, or the like. In one or more embodiments, the semiconductor layer may include polycrystalline silicon. The oxide semiconductor may be an oxide semiconductor containing indium (In). For example, the oxide semiconductor may be at least one selected from among indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

Although one first transistor T1 and one second transistor T2 are disposed in each subpixel SPXn of the display device 10 in the drawings, the present disclosure is not limited thereto, and the display device 10 may include a greater number of transistors.

A first gate insulating layer GI is disposed on the semiconductor layer and the buffer layer BL in the display area DPA. The first gate insulating layer GI may not be disposed in the pad area PDA. The first gate insulating layer GI may serve as a gate insulating film of each of the transistors T1 and T2. In one or more embodiments, the first gate insulating layer GI is disposed on the entire surface of the buffer layer BL, but the present disclosure is not limited thereto. In one or more embodiments, the first gate insulating layer GI may be patterned together with the gate electrodes G1 and G2 of the second conductive layer to be described later and thus may be partially disposed between the second conductive layer and the active layers ACT1 and ACT2 of the semiconductor layer (e.g., see FIG. 5).

The second conductive layer is disposed on the first gate insulating layer GI. The second conductive layer may include the first gate electrode G1 of the first transistor T1 and the second gate electrode G2 of the second transistor T2. The first gate electrode G1 may overlap a channel region of the first active layer ACT1 in the third direction DR3, which is the thickness direction of the substrate SUB, and the second gate electrode G2 may overlap a channel region of the second active layer ACT2 in the third direction DR3, which is the thickness direction of the substrate SUB. In one or more embodiments, the second conductive layer may further include one electrode of a storage capacitor.

A first interlayer insulating layer IL1 is disposed on the second conductive layer and the buffer layer BL. The first interlayer insulating layer IL1 may function as an insulating film between the second conductive layer and other layers disposed on the second conductive layer and may protect the second conductive layer.

The third conductive layer is disposed on the first interlayer insulating layer IL1. The third conductive layer may include a plurality of conductive patterns CDP1 through CDP3 and a source electrode S1 or S2 and a drain electrode D1 or D2 of the transistors T1 and T2. Some of the conductive patterns CDP1 through CDP3 may electrically connect conductive layers or semiconductor layers on different layers and may serve as source/drain electrodes of the transistors T1 and T2.

A first conductive pattern CDP1 may contact the first active layer ACT1 of the first transistor T1 through a contact hole penetrating the first interlayer insulating layer IL1. The first conductive pattern CDP1 may contact the bottom metal layer BML through a contact hole penetrating the first interlayer insulating layer IL1 and the buffer layer BL. The first conductive pattern CDP1 may serve as a first source electrode S1 of the first transistor T1. The first conductive pattern CDP1 may be electrically connected to the first electrode RME1 or the first connection electrode CNE1. The first transistor T1 may transmit the first power supply voltage received from the first voltage wiring VL1 to the first electrode RME1 or the first connection electrode CNE1.

The second conductive pattern CDP2 may contact the second voltage wiring VL2 through a contact hole penetrating the first interlayer insulating layer IL1 and the buffer layer BL. The second conductive pattern CDP2 may be electrically connected to the second electrode RME2 or the second connection electrode CNE2. The second voltage wiring VL2 may transmit the second power supply voltage to the second electrode RME2 or the second connection electrode CNE2.

The third conductive pattern CDP3 may contact the first voltage wiring VL1 through a contact hole penetrating the first interlayer insulating layer IL1 and the buffer layer BL. In addition, the third conductive pattern CDP3 may contact the first active layer ACT1 of the first transistor T1 through a contact hole penetrating the first interlayer insulating layer IL1. The third conductive pattern CDP3 may electrically connect the first voltage wiring VL1 to the first transistor T1 and may serve as a first drain electrode D1 of the first transistor T1.

Each of a second source electrode S2 and a second drain electrode D2 may contact the second active layer ACT2 of the second transistor T2 through a contact hole penetrating the first interlayer insulating layer IL1. The second transistor T2 may transmit a data signal to the first transistor T1 or transmit an initialization signal.

A first passivation layer PV1 is disposed on the third conductive layer. The first passivation layer PV1 may function as an insulating film between the third conductive layer and other layers and may protect the third conductive layer.

Each of the buffer layer BL, the first gate insulating layer GI, the first interlayer insulating layer IL1, and the first passivation layer PV1 described above may be composed of a plurality of inorganic layers stacked alternately. For example, each of the buffer layer BL, the first gate insulating layer GI, the first interlayer insulating layer IL1, and the first passivation layer PV1 may be a double layer in which inorganic layers including at least one selected from among silicon oxide (SiOₓ), silicon nitride (SiNₓ), and silicon oxynitride (SiOₓN_{y}) are stacked or may be a multilayer in which the above inorganic layers are alternately stacked. However, the present disclosure is not limited thereto, and each of the buffer layer BL, the first gate insulating layer GI, the first interlayer insulating layer IL1, and the first passivation layer PV1 may also be composed of one inorganic layer including one of the above insulating materials. In addition, in one or more embodiments, the first interlayer insulating layer IL1 may be made of an organic insulating material such as polyimide (PI).

A via layer VIA is disposed on the first passivation layer PV1 in the display area DPA. The via layer VIA may include an organic insulating material such as polyimide (PI) to compensate for a step difference due to the conductive layers thereunder and may form a substantially flat upper surface. However, in some embodiments, the via layer VIA may be omitted.

The display device 10 may include, as a display element layer disposed on the via layer VIA, the walls BP1 and BP2, the electrodes RME (RME1 and RME2), the bank layer BNL, the light emitting elements ED, and the connection electrodes CNE (CNE1 and CNE2). In addition, the display device 10 may include a plurality of insulating layers PAS1 through PAS3.

The walls BP1 and BP2 may be disposed on the via layer VIA. For example, the walls BP1 and BP2 may be directly disposed on the via layer VIA, and at least a portion of each of the walls BP1 and BP2 may protrude from the upper surface of the via layer VIA. However, the present disclosure is not limited thereto. The walls BP1 and BP2 may also not be directly disposed on the via layer VIA. The protruding portion of each of the walls BP1 and BP2 may have inclined side surfaces or curved side surfaces with a suitable curvature (e.g., a predetermined curvature), and light emitted from the light emitting elements ED may be reflected upward above the via layer VIA by the electrodes RME disposed on the walls BP1 and BP2. Unlike in the drawings, each of the walls BP1 and BP2 may also have a shape having an outer surface curved with a suitable curvature (e.g., a predetermined curvature) in cross section, for example, may have a semicircular or semielliptical shape. The walls BP1 and BP2 may include, but are not limited to, an organic insulating material such as polyimide (PI).

The electrodes RME (RME1 and RME2) may be disposed on the walls BP1 and BP2 and the via layer VIA. For example, the first electrode RME1 and the second electrode RME2 may be disposed on at least the inclined side surfaces of the walls BP1 and BP2. Widths of the electrodes RME measured in the second direction DR2 may be smaller than widths of the walls BP1 and BP2 measured in the second direction DR2, and a distance between the first electrode RME1 and the second electrode RME2 in the second direction DR2 may be smaller than a distance between the walls BP1 and BP2. At least a portion of each of the first electrode RME1 and the second electrode RME2 may be directly disposed on the via layer VIA so that they lie at the same plane.

The light emitting elements ED disposed between the walls BP1 and BP2 may emit light in directions toward both ends thereof, and the emitted light may travel toward the electrodes RME disposed on the walls BP1 and BP2. Each electrode RME may have a structure in which a portion disposed on a wall BP1 or BP2 can reflect light emitted from the light emitting elements ED. Each of the first electrode RME1 and the second electrode RME2 may cover at least one side surface of the wall BP1 or BP2 to reflect light emitted from the light emitting elements ED.

Each of the electrodes RME may directly contact the third conductive layer through an electrode contact hole CTD or CTS in a portion overlapping the bank layer BNL between the emission area EMA and the sub-area SA. A first electrode contact hole CTD may be formed in an area in which the bank layer BNL and the first electrode RME1 overlap, and a second electrode contact hole CTS may be formed in an area in which the bank layer BNL and the second electrode RME2 overlap. The first electrode RME1 may contact the first conductive pattern CDP1 through the first electrode contact hole CTD penetrating the via layer VIA and the first passivation layer PV1. The second electrode RME2 may contact the second voltage wiring VL2 through the second electrode contact hole CTS penetrating the via layer VIA and the first passivation layer PV1. The first electrode RME1 may be electrically connected to the first transistor T1 through the first conductive pattern CDP1 to receive the first power supply voltage, and the second electrode RME2 may be electrically connected to the second voltage wiring VL2 to receive the second power supply voltage. However, the present disclosure is not limited thereto. In one or more embodiments, the electrodes RME1 and RME2 may not be electrically connected to the voltage wirings VL1 and VL2 of the third conductive layer, and the connection electrodes CNE to be described later may be directly connected to the third conductive layer.

According to one or more embodiments, each of the electrodes RME1 and RME2 of the display device 10 may include a plurality of metal layers RML1 and RML2 including different materials. Each of the electrodes RME1 and RME2 of the display device 10 may include a first metal layer RML1 and a second metal layer RML2 disposed on the first metal layer RML1. Each of the electrodes RME1 and RME2 of the display device 10 may include the metal layers RML1 and RML2 including different materials to have a small taper angle. Accordingly, it is possible to reduce void or seam defects that may occur in a first insulating layer PAS1 disposed on the electrodes RME1 and RME2.

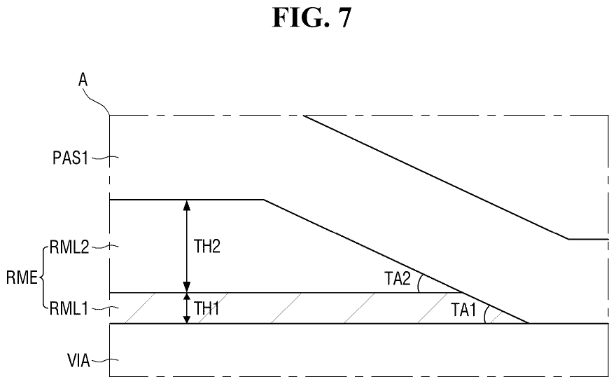

FIG. 7 is an enlarged view of a portion A of FIG. 5. FIG. 7 illustrates an enlarged view of an end of the first electrode RME1 in FIG. 5.

Referring to FIGS. 5 through 7, the first metal layer RML1 may be a base layer of each of the electrodes RME1 and RME2. The first metal layer RML1 of each of the electrodes RME1 and RME2 may be directly disposed on the via layer VIA or the wall BP1 or BP2. A lower surface of the first metal layer RML1 may contact the upper surface of the via layer VIA or the wall BP1 or BP2. The second metal layer RML2 may be an upper layer of each of the electrodes RME1 and RME2. The second metal layer RML2 of each of the electrodes RME1 and RME2 may be directly disposed on the first metal layer RML1, and a lower surface of the second metal layer RML2 may contact an upper surface of the first metal layer RML1. An upper surface of the second metal layer RML2 may contact a lower surface of the first insulating layer PAS1.

According to one or more embodiments, the first metal layer RML1 of each of the electrodes RME1 and RME2 may include a metal material having a higher standard reduction potential than the second metal layer RML2, and the second metal layer RML2 may include a material having high reflectivity and high electrical conductivity. In one or more embodiments, the first metal layer RML1 may include molybdenum (Mo), and the second metal layer RML2 may include an alloy including aluminum (Al), nickel (Ni), and lanthanum (La). Because the first metal layer RML1 includes molybdenum (Mo), interfacial adhesion between the second metal layer RML2 including an aluminum (Al) alloy and the first metal layer RML1 may be strong, and the metal layers RML1 and RML2 may be prevented from being partially peeled off during a manufacturing process of the display device 10.

Although the first metal layer RML1 and the second metal layer RML2 include different materials, they may be patterned in the same etching process to form the electrodes RME1 and RME2. Because the standard reduction potential of the first metal layer RML1 has a greater value than the standard reduction potential of the second metal layer RML2, an etch rate of the second metal layer RML2 may be higher than that of the first metal layer RML1 during a patterning process using an etchant. The second metal layer RML2 may be etched at a higher etch rate in an upper portion than in its lower surface in contact with the first metal layer RML1 and may have a small taper angle. In one or more embodiments, taper angles TA1 and TA2 of the metal layers RML1 and RML2 of each of the electrodes RME1 and RME2 may be 25 degrees or less or may be 5 to 25 degrees.

In FIG. 7, a first taper angle TA1 of the first metal layer RML1 is equal to a second taper angle TA2 of the second metal layer RML2. However, the present disclosure is not limited thereto. In one or more embodiments, the first taper angle TA1 of the first metal layer RML1 and the second taper angle TA2 of the second metal layer RML2 may be different. However, because the second metal layer RML2 is thicker than the first metal layer RML1 and occupies a larger proportion of each of the electrodes RME1 and RME2, at least the second taper angle TA2 of the second metal layer RML2 may be 25 degrees or less, and the first taper angle TA1 of the first metal layer RML1 may be greater than the second taper angle TA2.

The taper angles TA1 and TA2 of the first metal layer RML1 and the second metal layer RML2 may vary according to thicknesses of the metal layers RML1 and RML2, respectively. According to one or more embodiments, a thickness TH1 of the first metal layer RML1 may be between 100 Å to 300 Å, and a thickness TH2 of the second metal layer RML2 may be between 1000 Å to 2300 Å. In each of the electrodes RME1 and RME2, a total thickness (TH1+TH2) of the first metal layer RML1 and the second metal layer RML2 may be 2600 Å or less. When the thickness TH1 of the first metal layer RML1 is 100 Å or less, it may be difficult to form a metal layer, thus reducing processability. When the thickness TH1 of the first metal layer RML1 is 300 Å or more, the second taper angle TA2 of the second metal layer RML2 may be excessively small. If the second taper angle TA2 of the second metal layer RML2 is too small, a photoresist may be peeled off during the manufacturing process, causing the electrodes RME1 and RME2 to be lost. In addition, when the thickness TH1 of the first metal layer RML1 is too large, the first metal layer RML1 may be partially etched despite a difference in standard reduction potential from the second metal layer RML2. As a result, an undercut may be formed between the first metal layer RML1 and the second metal layer RML1. When the thickness TH2 of the second metal layer RML2 is 1000 Å or less, the thicknesses of the electrodes RME1 and RME2 may be too small, thus increasing electrical resistance. When the thickness TH2 of the second metal layer RML2 is 2300 Å or more, the taper angles TA1 and TA2 of the electrodes RME1 and RME2 may be too large. In the display device 10, each of the metal layers RML1 and RML2 of the electrodes RME1 and RME2 may have a thickness within the above-described range and may have a taper angle TA1 or TA2 of 25 degrees or less.

Because the taper angle is reduced at both ends of each of the electrodes RME1 and RME2, the material of the first insulating layer PAS1 may be smoothly deposited on the electrodes RME1 and RME2. In addition, because the insulating material is not deposited according to a step or slope thereunder, void or seam defects can be reduced or minimized. The smooth film quality of the first insulating layer PAS1 and the reduced defects may prevent a chemical solution from penetrating into defects of the first insulating layer PAS1 and damaging the electrodes RME1 and RME2 during a subsequent process in the manufacturing process of the display device 10.

The first insulating layer PAS1 may be disposed in the entire display area DPA and may be disposed on the via layer VIA and the electrodes RME. The first insulating layer PAS1 may protect the electrodes RME while insulating them from each other. Because the first insulating layer PAS1 covers the electrodes RME before the bank layer BNL is formed, it may prevent the electrodes RME from being damaged in the process of forming the bank layer BNL. In addition, the first insulating layer PAS1 may prevent direct contact of the light emitting elements ED on the first insulating layer PAS1 with other members and thus prevent damage to the light emitting elements ED.

In one or more embodiments, the first insulating layer PAS1 may be stepped such that a portion of an upper surface of the first insulating layer PAS1 is recessed between the electrodes RME that are spaced from each other in the second direction DR2. The light emitting elements ED may be disposed on the stepped upper surface of the first insulating layer PAS1, and a space may be formed between the light emitting elements ED and the first insulating layer PAS1.

The first insulating layer PAS1 may include the contact portions CT1 and CT2 disposed in the sub-area SA. The contact portions CT1 and CT2 may overlap different electrodes RME, respectively. For example, the first insulating layer PAS1 may include a first contact portion CT1 overlapping the first electrode RME1 and a second contact portion CT2 overlapping the second electrode RME2. Each of the first contact portion CT1 and the second contact portion CT2 may penetrate the first insulating layer PAS1 to expose a portion of an upper surface of the first electrode RME1 or the second electrode RME2 thereunder. Each of the first contact portion CT1 and the second contact portion CT2 may further penetrate some of the other insulating layers disposed on the first insulating layer PAS1. An electrode RME exposed by each of the contact portions CT1 and CT2 may contact a connection electrode CNE.

According to one or more embodiments, in the display device 10, because each of the electrodes RME includes a plurality of metal layers RML1 and RML2 including different materials and has a relatively small taper angle, the first insulating layer PAS1 may be disposed on the electrodes RME to form a smooth surface. As described above, in the display device 10, it is possible to prevent void or seam defects of the first insulating layer PAS1 and possible to prevent damage to the electrodes RME1 and RME2 by a chemical solution penetrating into the defects of the first insulating layer PAS1 during the manufacturing process.

The bank layer BNL may be disposed on the first insulating layer PAS1. The bank layer BNL may include portions extending in the first direction DR1 and the second direction DR2 and may be around (e.g., may surround) each subpixel SPXn. The bank layer BNL may surround the emission area EMA and the sub-area SA of each subpixel SPXn to separate them and may surround the outermost periphery of the display area DPA to separate the display area DPA and the non-display area NDA.

Like the walls BP1 and BP2, the bank layer BNL may have a suitable height (e.g., a predetermined height). In one or more embodiments, an upper surface of the bank layer BNL may be at a greater height than those of the walls BP1 and BP2, and a thickness of the bank layer BNL may be equal to or greater than those of the walls BP1 and BP2. The bank layer BNL may prevent ink from overflowing to adjacent subpixels SPXn in an inkjet printing process during the manufacturing process of the display device 10. Like the walls BP1 and BP2, the bank layer BNL may include an organic insulating material such as polyimide.

The light emitting elements ED may be disposed in the emission area EMA. The light emitting elements ED may be disposed on the first insulating layer PAS1 between the walls BP1 and BP2. A direction in which the light emitting elements ED extend may be substantially parallel to an upper surface of the first substrate SUB1. As will be described later, each light emitting element ED may include a plurality of semiconductor layers disposed along the direction in which the light emitting element ED extends, and the semiconductor layers may be sequentially disposed along a direction parallel to the upper surface of the first substrate SUB. However, the present disclosure is not limited thereto. When each of the light emitting elements ED has a different structure, the semiconductor layers may be disposed in a direction perpendicular to the first substrate SUB.

The light emitting elements ED disposed in the subpixels SPXn may emit light of different wavelength bands depending on the materials that form the semiconductor layers described above. However, the present disclosure is not limited thereto, and the light emitting elements ED disposed in the subpixels SPXn may also emit light of the same color by including the semiconductor layers made of the same material.

The light emitting elements ED may be electrically connected to the electrodes RME and the conductive layers under the via layer VIA by contacting the connection electrodes CNE (CNE1 and CNE2) and may emit light of a specific wavelength band in response to an electrical signal.

A second insulating layer PAS2 may be disposed on the light emitting elements ED, the first insulating layer PAS1, and the bank layer BNL. The second insulating layer PAS2 includes a pattern portion extending in the first direction DR1 between the walls BP1 and BP2 and disposed on the light emitting elements ED. The pattern portion may partially cover outer surfaces (e.g., outer peripheral or circumferential surfaces) of the light emitting elements ED but may not cover both sides or both ends of the light emitting elements ED. The pattern portion may form a linear or island-shaped pattern in each subpixel SPXn in a plan view. The pattern portion of the second insulating layer PAS2 may protect the light emitting elements ED while anchoring the light emitting elements ED in the manufacturing process of the display device 10. The second insulating layer PAS2 may also fill the space between the light emitting elements ED and the first insulating layer PAS1 under the light emitting elements ED. In addition, a portion of the second insulating layer PAS2 may be disposed on the bank layer BNL and in the sub-areas SA.

The connection electrodes CNE (CNE1 and CNE2) may be disposed on the electrodes RME and the walls BP1 and BP2. The first connection electrode CNE1 may be disposed on the first electrode RME1 and the first wall BP1. The first connection electrode CNE1 may partially overlap the first electrode RME1 and may extend from the emission area EMA to the sub-area SA beyond the bank layer BNL. The second connection electrode CNE2 may be disposed on the second electrode RME2 and the second wall BP2. The second connection electrode CNE2 may partially overlap the second electrode RME2 and may extend from the emission area EMA to the sub-area SA beyond the bank layer BNL.

Each of the first connection electrode CNE1 and the second connection electrode CNE2 may contact the light emitting elements ED. The first connection electrode CNE1 may partially overlap the first electrode RME1 and may contact an end of each light emitting element ED. The second connection electrode CNE2 may partially overlap the second electrode RME2 and may contact the other end of each light emitting element ED. The connection electrodes CNE are disposed over the emission area EMA and the sub-area SA. Each of the connection electrodes CNE may contact the light emitting elements ED in a portion disposed in the emission area EMA and may be electrically connected to the third conductive layer in a portion disposed in the sub-area SA. The first connection electrode CNE1 may contact first ends of the light emitting elements ED, and the second connection electrode CNE2 may contact second ends of the light emitting elements ED.

In the display device 10, each of the connection electrodes CNE may contact an electrode RME through a contact portion CT1 or CT2 disposed in the sub-area SA. The first connection electrode CNE1 may contact the first electrode RME1 through the first contact portion CT1 penetrating the first insulating layer PAS1, the second insulating layer PAS2, and a third insulating layer PAS3 in the sub-area SA. The second connection electrode CNE2 may contact the second electrode RME2 through the second contact portion CT2 penetrating the first insulating layer PAS1 and the second insulating layer PAS2 in the sub-area SA. The connection electrodes CNE may be electrically connected to the third conductive layer through the electrodes RME, respectively. The first connection electrode CNE1 may be electrically connected to the first transistor T1 to receive the first power supply voltage, and the second connection electrode CNE2 may be electrically connected to the second voltage wiring VL2 to receive the second power supply voltage. Each of the connection electrodes CNE may contact the light emitting elements ED in the emission area EMA to transmit a power supply voltage to the light emitting elements ED.

However, the present disclosure is not limited thereto. In one or more embodiments, the connection electrodes CNE may directly contact the third conductive layer or may be electrically connected to the third conductive layer through patterns other than the electrodes RME.

The connection electrodes CNE may include a conductive material such as ITO, IZO, ITZO, or aluminum (Al). For example, the connection electrodes CNE may include a transparent conductive material, and light emitted from the light emitting elements ED may be output through the connection electrodes CNE.

The third insulating layer PAS3 is disposed on the second connection electrode CNE2 and the second insulating layer PAS2. The third insulating layer PAS3 may be disposed on the entire surface of the second insulating layer PAS2 to cover the second connection electrode CNE2, and the first connection electrode CNE1 may be disposed on the third insulating layer PAS3. The third insulating layer PAS3 may be disposed on the entire surface of the via layer VIA except for an area in which the first connection electrode CNE1 is disposed. The third insulating layer PAS3 may insulate the first connection electrode CNE1 and the second connection electrode CNE2 from each other so that they do not directly contact each other.

In one or more embodiments, another insulating layer may be further disposed on the third insulating layer PAS3 and the first connection electrode CNE1. The insulating layer may protect members disposed on the first substrate SUB from an external environment.

Each of the first insulating layer PAS1, the second insulating layer PAS2, and the third insulating layer PAS3 described above may include an inorganic insulating material or an organic insulating material. For example, each of the first insulating layer PAS1, the second insulating layer PAS2, and the third insulating layer PAS3 may include an inorganic insulating material, or the first insulating layer PAS1 and the third insulating layer PAS3 may include an inorganic insulating material, but the second insulating layer PAS2 may include an organic insulating material. Each or at least any one of the first insulating layer PAS1, the second insulating layer PAS2, and the third insulating layer PAS3 may be formed in a structure in which a plurality of insulating layers are alternately or repeatedly stacked. In one or more embodiments, each of the first insulating layer PAS1, the second insulating layer PAS2, and the third insulating layer PAS3 may be one or more selected from among silicon oxide (SiOₓ), silicon nitride (SiNₓ), and silicon oxynitride (SiOₓN_{y}). The first insulating layer PAS1, the second insulating layer PAS2, and the third insulating layer PAS3 may be made of the same material, or some may be made of the same material while the other is made of a different material, or all of them may be made of different materials.

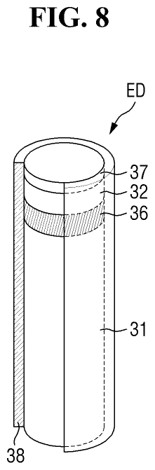

FIG. 8 is a schematic cutaway view of a light emitting element ED according to one or more embodiments.

Referring to FIG. 8, the light emitting element ED may be a light emitting diode. Specifically, the light emitting element ED may be an inorganic light emitting diode having a size in a nanometer or micrometer range and may be made of an inorganic material. When an electric field is formed in a specific direction between two electrodes facing each other, the light emitting element ED may be aligned between the two electrodes to which different suitable voltages have been applied.

The light emitting element ED according to one or more embodiments may extend in one direction. The light emitting element ED may be shaped like a cylinder, a rod, a wire, a tube, or the like. However, the shape of the light emitting element ED is not limited thereto, and the light emitting element ED may also have various shapes including polygonal prisms, such as a cube, a rectangular parallelepiped or a hexagonal prism, and a shape extending in a direction and having a partially inclined outer surface.

The light emitting element ED may include a semiconductor layer doped with a dopant of any conductivity type (e.g., a p-type or an n-type). The semiconductor layer may receive an electrical signal from an external power source and emit light of a specific wavelength band. The light emitting element ED may include a first semiconductor layer 31, a second semiconductor layer 32, a light emitting layer 36, an electrode layer 37, and an insulating film 38.

The first semiconductor layer 31 may be an n-type semiconductor. The first semiconductor layer 31 may include a semiconductor material having a chemical formula of AlₓGa_{y}In_{1-x-y}N(0≤x≤1, 0≤y≤1, 0≤c+y≤1). For example, the first semiconductor layer 31 may be one or more selected from among AlGaInN, GaN, AlGaN, InGaN, AlN, and InN doped with an n-type dopant. The n-type dopant used to dope the first semiconductor layer 31 may be Si, Ge, Sn, Se, or the like.

The second semiconductor layer 32 is disposed on the first semiconductor layer 31 with the light emitting layer 36 interposed between them. The second semiconductor layer 32 may be a p-type semiconductor. The second semiconductor layer 32 may include a semiconductor material having a chemical formula of AlₓGa_{y}In_{1-x-y}N(0≤x≤1, 0≤y≤1, 0≤x+y≤1). For example, the second semiconductor layer 32 may be one or more selected from among AlGaInN, GaN, AlGaN, InGaN, AlN, and InN doped with a p-type dopant. The p-type dopant used to dope the second semiconductor layer 32 may be Mg, Zn, Ca, Ba, or the like.

Although each of the first semiconductor layer 31 and the second semiconductor layer 32 is composed of one layer in the drawing, the present disclosure is not limited thereto. Each of the first semiconductor layer 31 and the second semiconductor layer 32 may also include more layers, for example, may further include a clad layer or a tensile strain barrier reducing (TSBR) layer depending on the material of the light emitting layer 36. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may be one or more selected from among AlGaInN, GaN, AlGaN, InGaN, AlN, InN, and SLs doped with an n-type dopant. The semiconductor layer disposed between the second semiconductor layer 32 and the light emitting layer 36 may be one or more selected from among AlGaInN, GaN, AlGaN, InGaN, AlN, and InN doped with a p-type dopant.

The light emitting layer 36 is disposed between the first semiconductor layer 31 and the second semiconductor layer 32. The light emitting layer 36 may include a material having a single or multiple quantum well structure. When the light emitting layer 36 includes a material having a multiple quantum well structure, it may have a structure in which a plurality of quantum layers and a plurality of well layers are alternately stacked. The light emitting layer 36 may emit light through combination of electron-hole pairs according to electrical signals received through the first semiconductor layer 31 and the second semiconductor layer 32. The light emitting layer 36 may include a material such as AlGaN, AlGaInN, or InGaN. In particular, when the light emitting layer 36 has a multiple quantum well structure in which a quantum layer and a well layer are alternately stacked, the quantum layer may include a material such as AlGaN or AlGaInN, and the well layer may include a material such as GaN or AlInN.

The light emitting layer 36 may also have a structure in which a semiconductor material having a large band gap energy and a semiconductor material having a small band gap energy are alternately stacked or may include different Group III to V semiconductor materials depending on the wavelength band of light that it emits. Light emitted from the light emitting layer 36 is not limited to light in a blue wavelength band. In some cases, the light emitting layer 36 may emit light in a red or green wavelength band.

The electrode layer 37 may be an ohmic connection electrode. However, the present disclosure is not limited thereto, and the electrode layer 37 may also be a Schottky connection electrode. The light emitting element ED may include at least one electrode layer 37 at one end of the light emitting element ED. For example, the electrode layer 37 may be disposed on the second semiconductor layer 32 or the first semiconductor layer 31. The light emitting element ED may include one or more electrode layers 37. However, the present disclosure is not limited thereto, and the electrode layer 37 may also be omitted.

When the light emitting element ED is electrically connected to an electrode or a connection electrode in the display device 10, the electrode layer 37 may reduce the resistance between the light emitting element ED and the electrode or the connection electrode. The electrode layer 37 may include a conductive metal. For example, the electrode layer 37 may include at least one selected from among aluminum (Al), titanium (Ti), indium (In), gold (Au), silver (Ag), indium tin oxide (ITO), indium zinc oxide (IZO), and indium tin zinc oxide (ITZO).

The insulating film 38 may be around (may surround) outer surfaces (e.g., outer peripheral or circumferential surfaces) of the semiconductor layers and the electrode layer described above. For example, the insulating film 38 may be around (e.g., may surround) an outer surface (e.g., an outer peripheral or circumferential surface) of at least the light emitting layer 36 but may expose both ends of the light emitting element ED in a longitudinal direction. In addition, an upper surface of the insulating film 38 may be rounded in cross section in an area adjacent to at least one end of the light emitting element ED.

The insulating film 38 may include an insulating material, for example, at least one selected from among silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). Although the insulating film 38 is illustrated as a single layer in the drawing, the present disclosure is not limited thereto. In one or more embodiments, the insulating film 38 may be formed in a multilayer structure in which a plurality of layers are stacked.

The insulating film 38 may protect the semiconductor layers and the electrode layer of the light emitting element ED. The insulating film 38 may prevent an electrical short circuit that may occur in the light emitting layer 36 when the light emitting layer 36 directly contacts an electrode that transmits an electrical signal to the light emitting element ED. In addition, the insulating film 38 may prevent a reduction in luminous efficiency of the light emitting element ED.

In addition, an outer surface (e.g., an outer peripheral or circumferential surface) of the insulating film 38 may be treated. The light emitting element ED may be sprayed onto electrodes in a state where it is dispersed in a suitable ink (e.g., a predetermined ink) and then may be aligned. Here, the surface of the insulating film 38 may be hydrophobic or hydrophilic-treated so that the light emitting element ED is kept separate in the ink without being agglomerated with other adjacent light emitting elements ED.

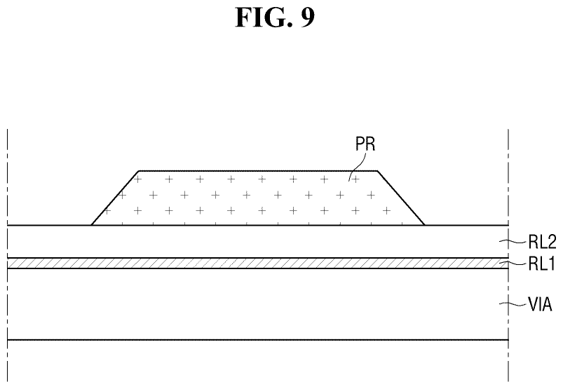

FIGS. 9 through 12 are cross-sectional views schematically illustrating a process of forming electrodes of the display device 10 according to one or more embodiments. In FIGS. 9 through 12, a process of forming the first metal layer RML1 and the second metal layer RML2 is illustrated as a process of forming the electrodes RME1 and RME2 of the display device 10.

First, referring to FIG. 9, a first metal material layer RL1 and a second metal material layer RL2 are sequentially formed on the via layer VIA, and a photoresist PR is placed on the second metal material layer RL2 along the shape of each electrode RME. The first metal material layer RL1 and the second metal material layer RL2 may be formed by a conventional process. For example, the first metal material layer RL1 and the second metal material layer RL2 may be formed by a process such as atomic layer deposition (ALD), chemical vapor deposition (CVD), physical vapor deposition (PVD), or sputtering. The photoresist PR may also be formed by a conventional process. For example, the photoresist PR may be formed by forming a photosensitive material and then exposing and developing the photoresist material using a mask to form a pattern.

The first metal material layer RL1 and the second metal material layer RL2 may be patterned in a subsequent process to form the first metal layer RML1 and the second metal layer RML2 of each electrode RME of the display device 10, respectively. The first metal material layer RL1 and the second metal material layer RL2 may include the same metal material as the first metal layer RML1 and the second metal layer RML2, respectively. For example, the first metal material layer RL1 may include molybdenum (Mo), and the second metal material layer RL2 may be made of an alloy including aluminum (Al), nickel (Ni) and lanthanum (La).

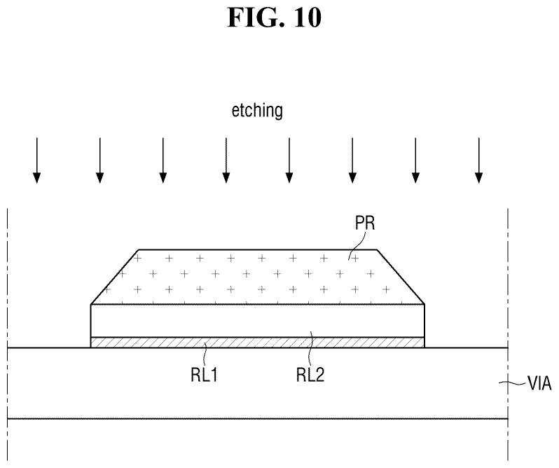

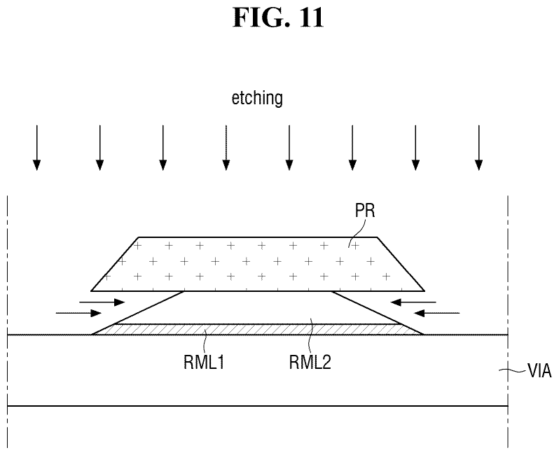

Next, referring to FIGS. 10 and 11, the first metal material layer RL1 and the second metal material layer RL2 are etched to form the first metal layer RML1 and the second metal layer RML2 of each electrode RME. The first metal material layer RL1 and the second metal material layer RL2 may include different metal materials, but may be etched by the same etchant. However, the first metal material layer RL1 may include a metal having a higher standard reduction potential than that of the second metal material layer RL2, and an etch rate of the second metal material layer RL2 may be higher than that of the first metal material layer RL1.

As illustrated in FIG. 11, when the first metal material layer RL1 and the second metal material layer RL2 are patterned using the photoresist PR as a mask, a portion covered by the photoresist PR may be partially etched by an etchant. Accordingly, each of the first metal layer RML1 and the second metal layer RML2 formed by etching the first metal material layer RL1 and the second metal material layer RL2 may have a smaller width than the photoresist PR.

Due to a difference in standard reduction potential between the first metal material layer RL1 and the second metal material layer RL2, the etch rate of the second metal material layer RL2 may be higher than that of the first metal material layer RL1. In addition, the etch rate of the second metal material layer RL1 may be higher in an upper portion than in a lower portion thereof. Accordingly, an upper surface of the second metal material layer RL2 in contact with the photoresist PR may be etched more, and the first metal layer RML1 and the second metal layer RML2 may have a small taper angle.

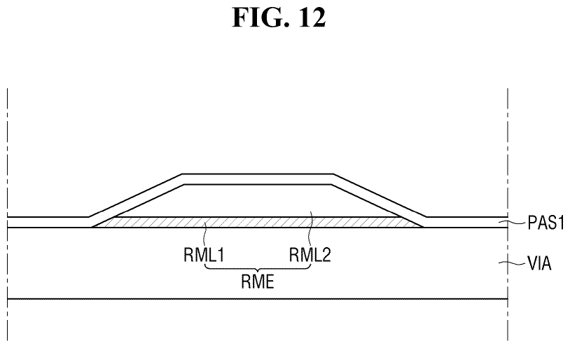

Next, referring to FIG. 12, the first insulating layer PAS1 is formed on the first metal layer RML1 and the second metal layer RML2. Because the metal layers RML1 and RML2 under the first insulating layer PAS1 have a small taper angle, the first insulating layer PAS1 may be formed to have a uniform film quality along the gentle slope of the metal layers RML1 and RML2. Therefore, it is possible to prevent the first insulating layer PAS1 from void or seam defects due to a step difference between the metal layers RML1 and RML2 under the first insulating layer PAS1 and possible to prevent damage to the electrodes RME by the defects of the first insulating layer PAS1 in the manufacturing process of the display device 10.

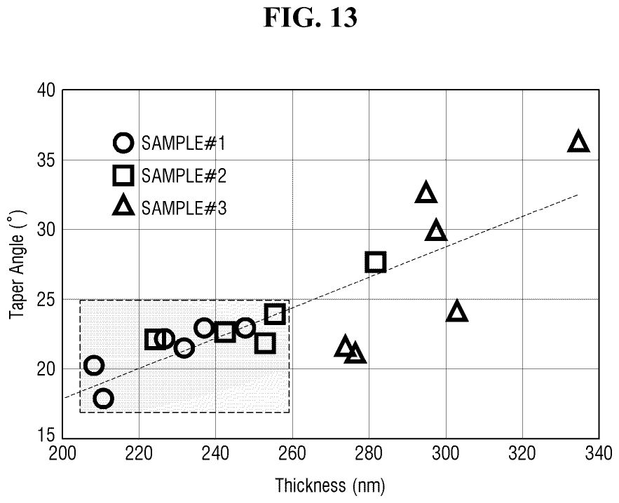

FIG. 13 is a graph illustrating a taper angle with respect to the thickness of each layer of electrodes according to one or more embodiments. FIG. 13 illustrates the change in taper angle with respect to the thickness of an electrode RME including the first metal layer RML1 made of molybdenum (Mo) and the second metal layer RML2 made of an alloy including aluminum (Al), nickel (Ni) and lanthanum (La). In FIG. 13, SAMPLE #1, SAMPLE #2, and SAMPLE #3 each show the change in taper angle with respect to the thickness of the second metal layer RML2 and the thickness of the electrode RME in a state where the first metal layer RML1 has a thickness of 200 Å. In the graph of FIG. 13, the X axis represents the total thickness of the first metal layer RML1 and the second metal layer RML2, and the Y axis represents the taper angle of the electrode RME.

Referring to FIG. 13, the taper angle of the electrode RME including the first metal layer RML1 and the second metal layer RML2 may vary according to the total thickness of the electrode RME in addition to the materials of the first metal layer RML1 and the second metal layer RML2. In each sample illustrated in the graph of FIG. 13, the first metal layer RML1 may be made of molybdenum (Mo) having a thickness of 200 Å, and the total thickness and taper angle of the electrode RME may vary according to the thickness of the second metal layer RML2.

When the total thickness of the electrode RME is 2600 Å or less, the taper angle of the electrode RME including the first metal layer RML1 and the second metal layer RML2 may have a value of 25 degrees or less. On the other hand, when the total thickness of the electrode RME is 2600 Å or more, even if the first metal layer RML1 is made of molybdenum (Mo) having a thickness of 200 Å, the taper angle of the electrode RME may have a value of 25 degrees or more.

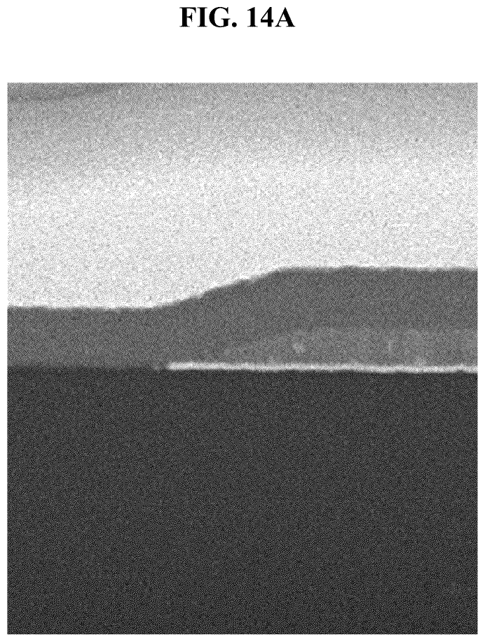

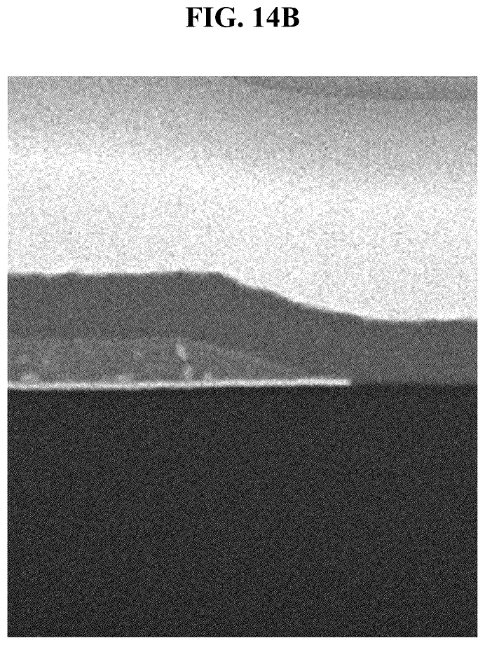

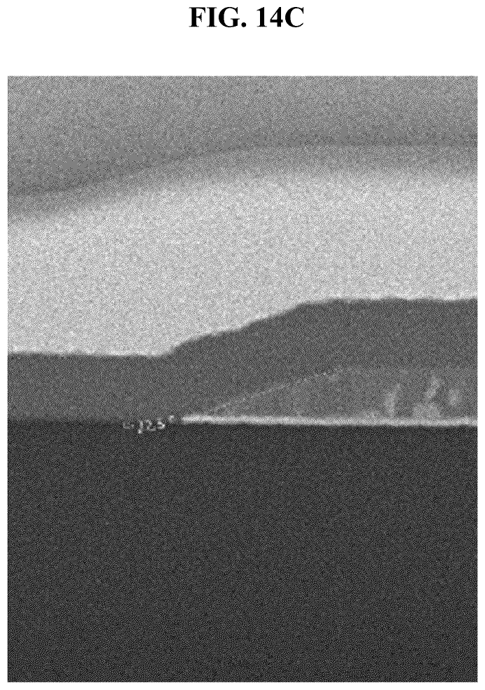

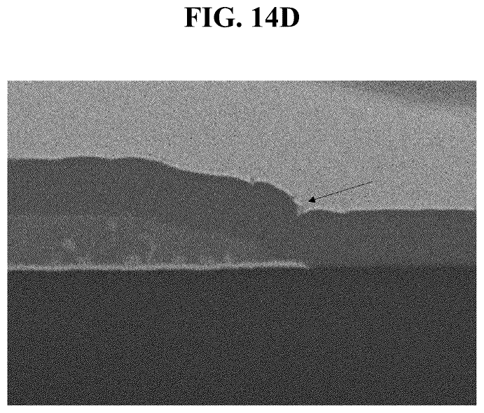

FIGS. 14A through 14D are photomicrographs showing a taper angle according to the thickness of an electrode according to one or more embodiments. FIGS. 14A through 14D each show the first metal layer RML1 having a thickness of 200 Å, a taper angle that varies according to the thicknesses of the second metal layer RML2 and an electrode RME, and the film quality of an insulating layer disposed on the second metal layer RML2 and the electrode RME.

In the electrode RME of FIG. 14A, the thickness of the first metal layer RML1 is 200 Å, the total thickness is 2110 Å, and the taper angle is 18.9 degrees. In the electrode RME of FIG. 14B, the thickness of the first metal layer RML1 is 200 Å, the total thickness is 2310 Å, and the taper angle is 20.8 degrees. In the electrode RME of FIG. 14C, the thickness of the first metal layer RML1 is 200 Å, the total thickness is 2470 Å, and the taper angle is 22.5 degrees. On the other hand, in the electrode RME of FIG. 14D, the thickness of the first metal layer RML1 is 200 Å, the total thickness is 2600 Å or more, and the taper angle is 40 degrees or more.

Referring to FIGS. 14A through 14D, it can be seen that the taper angle varies according to the total thickness of the electrode RME even if the first metal layer RML1 having the same thickness is included. As apparent from the electrodes RME of FIGS. 14A through 14C, when the total thickness is 2600 Å or less, the taper angle has a value of 25 degrees or less, and the insulating layer disposed on the electrodes RME has a uniform film quality. On the other hand, as apparent from FIG. 14D, when the total thickness of the electrode RME is 2600 Å or more, the taper angle has a value of degrees or more. Therefore, a seam defect (a portion indicated by an arrow) occurs in the insulating layer disposed on the electrode RME.

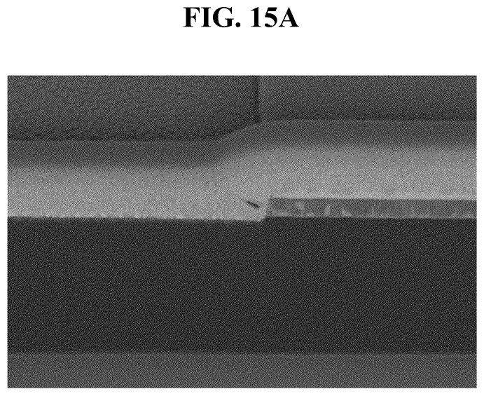

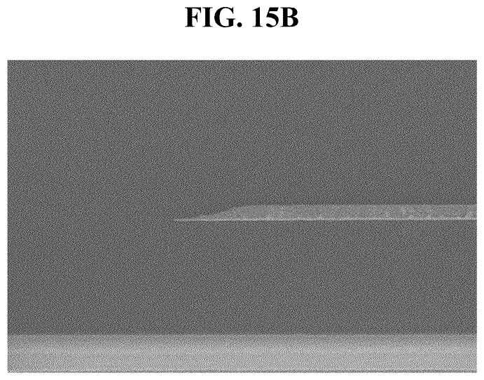

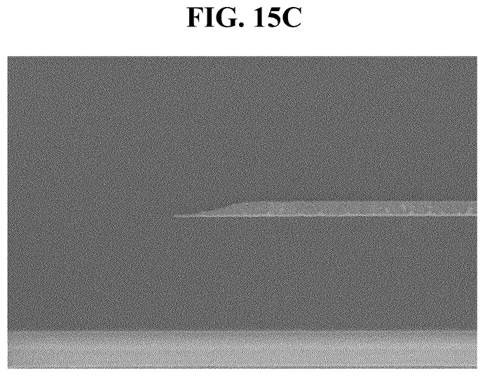

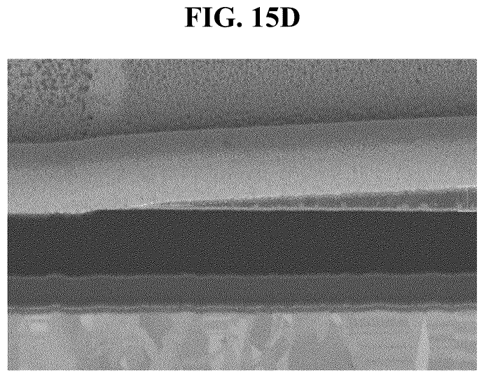

FIGS. 15A through 15D are photomicrographs showing a taper angle according to the thickness of a first metal layer of an electrode according to one or more embodiments. FIGS. 15A through 15D show the change in taper angle according to the thickness of the first metal layer RML1 in an electrode RME including the first metal layer RML1 made of molybdenum (Mo) and the second metal layer RML2 made of an alloy including aluminum (Al), nickel (Ni) and lanthanum (La). FIG. 15A shows a cross section of an electrode including only the second metal layer RML2 without the first metal layer RML1. FIGS. 15B through 15D show cross sections of electrodes including the first metal layers RML1 having thicknesses of 100 Å, 200 Å, and 300 Å, respectively.

In the electrode RME of FIG. 15A, the total thickness is 1859 Å, and the taper angle is 76.0 degrees. In the electrode RME of FIG. 15B, the thickness of the first metal layer RML1 is 100 Å, the total thickness is 2445 Å, and the taper angle is 18.8 degrees. In the electrode RME of FIG. 15C, the thickness of the first metal layer RML1 is 200 Å, the total thickness is 2445 Å, and the taper angle is 18.8 degrees. In the electrode RME of FIG. 15D, the thickness of the first metal layer RML1 is 300 Å, the total thickness is 2558 Å or more, and the taper angle is 7.8 degrees.

Referring to FIGS. 15A through 15D, it can be seen that the taper angle of an electrode RME is reduced when the electrode RME includes the first metal layer RML1 and the second metal layer RML2 made of different metal materials. The electrodes RME of FIGS. 15B through 15D including the first metal layer RML1 may have a taper angle of 20 degrees or less even if the total thickness is 2400 Å or more. On the other hand, the electrode RME of FIG. 15A not including the first metal layer RML1 may have a taper angle of 76.0 degrees even if it has a relatively small total thickness of 1859 Å. This shows that the taper angle may be reduced when an electrode RME includes the first metal layer RML1.

In addition, it can be seen from the comparison of FIGS. 15B through 15D that the taper angle of an electrode RME decreases as the thickness of the first metal layer RML1 increases. However, when the thickness of the first metal layer RML1 is 300 Å (FIG. 15D), the taper angle of the electrode RME may be 7.8 degrees. Here, if the thickness of the first metal layer RML1 is further increased, the taper angle of the electrode RME may become too small. When the taper angle of the electrode RME is too small, there is a risk that the photoresist PR may be peeled off during the process of forming the metal layers RML1 and RML2. Hence, the thickness of the first metal layer RML1 may be 300 Å or less.

In the display device 10 according to one or more embodiments, each electrode RME may have a taper angle of 25 degrees or less by including the first metal layer RML1 and the second metal layer RML2 made of different metal materials and having certain thicknesses, respectively. Accordingly, the first insulating layer PAS1 disposed on the electrodes RME may be prevented from void or seam defects that may occur due to a step difference of the electrodes RME under the first insulating layer PAS1. In addition, the first insulating layer PAS1 may be formed to have a uniform film quality. In the display device 10, it is possible to prevent damage to the electrodes RME by defects occurring in the first insulating layer PAS1.

Other embodiments of the display device 10 will now be described with reference to other drawings.

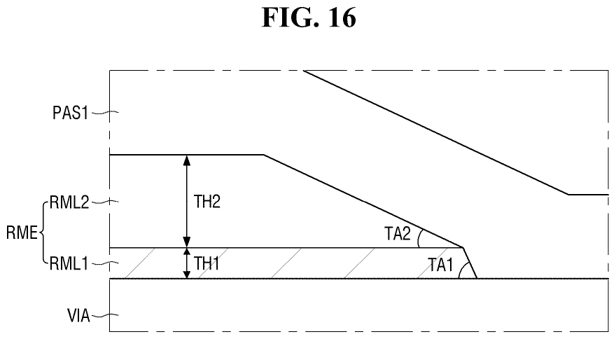

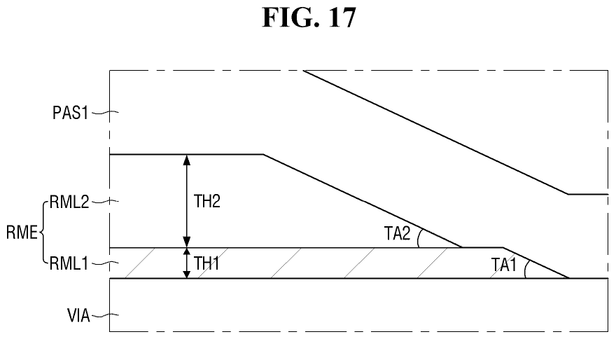

FIGS. 16 and 17 are cross-sectional views illustrating an end of an electrode RME in display devices 10 according to one or more embodiments.

Referring to FIG. 16, in a display device 10, a first taper angle TA1 of a first metal layer RML1 may be greater than a second taper angle TA2 of a second metal layer RML2. As described above, the first metal layer RML1 and the second metal layer RML2 may include different metal materials, but may be etched by the same etchant. However, etch rates of the different metal layers RML1 and RML2 may be different due to a difference in material and a difference in standard reduction potential. In one or more embodiments, in the electrode RME of the display device 10, the first taper angle TA1 of the first metal layer RML1 and the second taper angle TA2 of the second metal layer RML2 may be different from each other. Because a thickness TH1 of the first metal layer RML1 is smaller than a thickness TH2 of the second metal layer RML2 in the electrode RME, the total thickness and taper angle of the electrode RME may be close to the thickness TH2 and the taper angle TA2 of the second metal layer RML2. Even if the first taper angle TA1 of the first metal layer RML1 is relatively large, if the second taper angle TA2 of the second metal layer RML2 is sufficiently small, a first insulating layer PAS1 disposed on the electrode RME may have a uniform film quality.

In one or more embodiments, the first taper angle TA1 of the first metal layer RML1 may be 25 degrees or more, but at least the second taper angle TA2 of the second metal layer RML2 may be 25 degrees or less. Accordingly, the first insulating layer PAS1 disposed on the second metal layer RML2 of the electrode RME may have a uniform film quality without void or seam defects.

Referring to FIG. 17, in a display device 10, a width of a second metal layer RML2 may be smaller than a width of a first metal layer RML1, and an end of the second metal layer RML2 may be recessed inward from an end of the first metal layer RML1. As described above, even if the first metal layer RML1 and the second metal layer RML2 are etched by the same etchant, they may have different etch rates because they include different metal materials. An upper portion of the second metal layer RML2 may be etched before a lower portion due to a difference in etch rate. Depending on the degree to which the second metal layer RML2 is etched, the lower portion of the second metal layer RML2 may be etched more than an upper portion of the first metal layer RML1. Accordingly, an end of a lower surface of the second metal layer RML2 may be recessed inward from an end of an upper surface of the first metal layer RML1, and a width of a lower end of the second metal layer RML2 may be smaller than a width of an upper end of the first metal layer RML1. However, because a thickness TH1 of the first metal layer RML1 is smaller than a thickness TH2 of the second metal layer RML2 in the electrode RME, the total thickness and taper angle of the electrode RME may be close to the thickness TH2 and the taper angle TA2 of the second metal layer RML2. Accordingly, even if the first metal layer RML1 and the second metal layer RML2 have a partially stepped shape, a first insulating layer PAS1 disposed on the first metal layer RML1 and the second metal layer RML2 may have a uniform film quality as long as the taper angle TA2 of the second metal layer RML2 is 25 degrees or less.

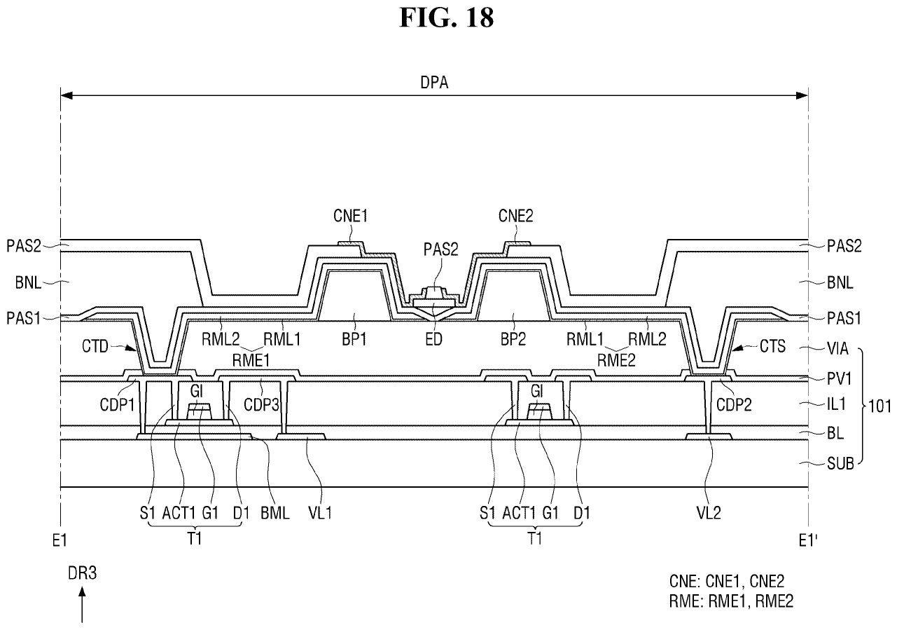

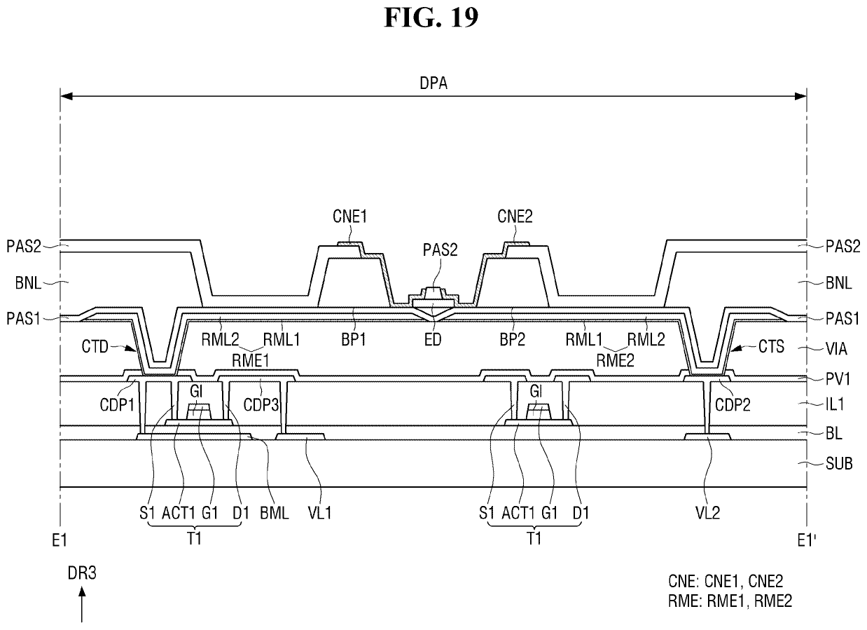

FIGS. 18 and 19 are cross-sectional views of the display devices 10 according to one or more embodiments.

Referring to FIG. 18, a third insulating layer PAS3 may be omitted, and a first connection electrode CNE1 and a second connection electrode CNE2 may be disposed on (or at) the same layer. Unlike in the embodiment of FIGS. 5 and 6, in a display device 10 according to the current embodiment, the third insulating layer PAS3 may be omitted, and a second insulating layer PAS2 may include an organic insulating material. Therefore, the first connection electrode CNE1 and the second connection electrode CNE2 may be directly disposed on the second insulating layer PAS2.

The display device 10 may include the second insulating layer PAS2 and the third insulating layer PAS3, each including an inorganic insulating material, or may include the second insulating layer PAS2 including an organic insulating material without including the third insulating layer PAS3. The second insulating layer PAS2 may be relatively thick by including an organic insulating material. The first connection electrode CNE1 and the second connection electrode CNE2 may be directly disposed on the second insulating layer PAS2 and may be disposed on substantially the same layer. A pattern portion of the second insulating layer PAS2, which is disposed on light emitting elements ED, may have both side surfaces in contact with the connection electrodes CNE1 and CNE2, respectively.

Referring to FIG. 19, in a display device 10 according to one or more embodiments, walls BP1 and BP2 may be disposed on electrodes RME1 and RME2 and a first insulating layer PAS1, and a second insulating layer PAS2 and connection electrodes CNE1 and CNE2 may be partially directly disposed on the walls BP1 and BP2. The display device 10 according to the current embodiment is different from that of the embodiment of FIG. 18 in positions of the walls BP1 and BP2.

In the embodiment of FIGS. 5 and 6, the walls BP1 and BP2 are disposed between the electrodes RME1 and RME2 and a via layer VIA to form an area in which light emitting elements ED are disposed and to serve as reflective walls that reflect light emitted from the light emitting elements ED in an upward direction. However, if the direction of light emitted from the light emitting elements ED is designed to be the upward direction above the via layer VIA, there is no need for the walls BP1 and BP2 to serve as the reflective walls. In this case, the electrodes RME1 and RME2 may not necessarily be disposed on the walls BP1 and BP2, and conversely, the walls BP1 and BP2 may be disposed on the electrodes RME1 and RME2. The walls BP1 and BP2 may overlap the electrodes RME1 and RME2 in the thickness direction (e.g., the third direction DR3) to form the area in which the light emitting elements ED are disposed between the walls BP1 and BP2.

The electrodes RME1 and RME2 may be directly disposed on the via layer VIA, and the walls BP1 and BP2 may be directly disposed on the first insulating layer PAS1 while overlapping the electrodes RME1 and RME2 in the thickness direction (e.g., the third direction DR3). The second insulating layer PAS2 and the connection electrodes CNE1 and CNE2 may be partially directly disposed on the walls BP1 and BP2. Because the electrodes RME1 and RME2 are directly disposed on the via layer VIA, a step difference according to position may be further reduced, and the first insulating layer PAS1 disposed on the electrodes RME1 and RME2 may be further prevented from having defects due to a step difference under the first insulating layer PAS1.

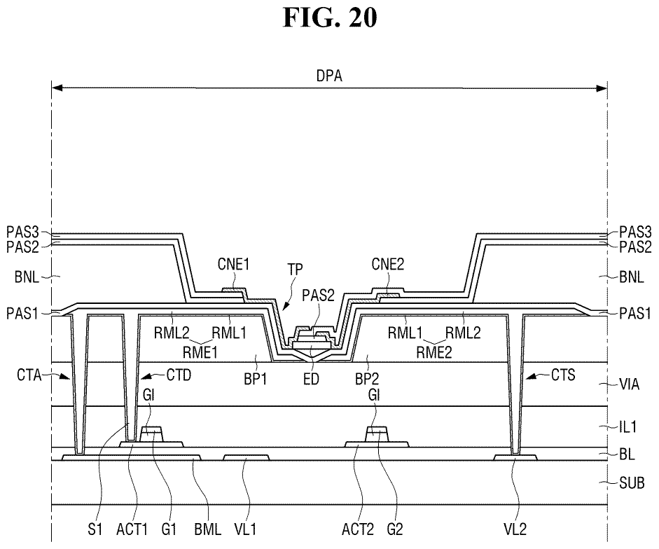

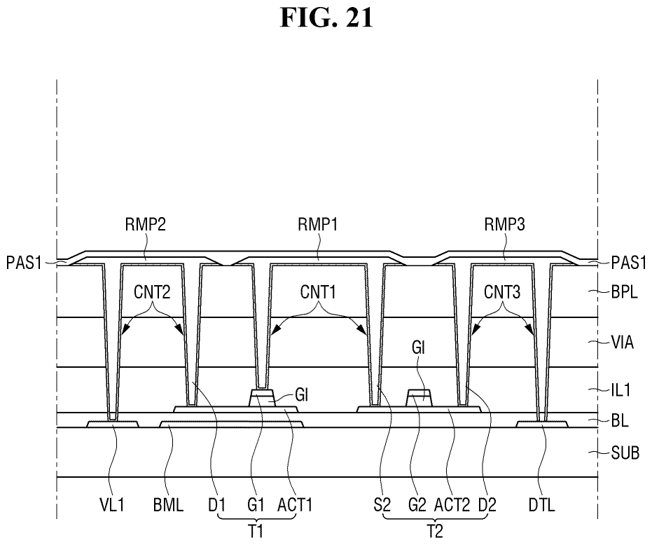

FIGS. 20 and 21 are cross-sectional views of a display device 10 according to one or more embodiments.

Referring to FIGS. 20 and 21, in the display device 10 according to one or more embodiments, a third conductive layer may be omitted, and electrodes RME1 and RME2 and electrode patterns RMP1 through RMP3 disposed on (or at) the same layer as the electrodes RME1 and RME2 may directly contact a first conductive layer, a second conductive layer, and a semiconductor layer. A manufacturing process of the display device 10 according to the current embodiment is shortened because the third conductive layer is omitted.

A first electrode RME1 may be disposed on a first wall BP1 and may directly contact the first conductive layer and the semiconductor layer through electrode contact holes CTA and CTD. The first electrode RME1 may directly contact a first active layer ACT1 of a first transistor T1 through a first electrode contact hole CTD penetrating the first wall BP1, a via layer VIA, and a first interlayer insulating layer IL1. In addition, the first electrode RME1 may directly contact a bottom metal layer BML through a third electrode contact hole CTA penetrating the first wall BP1, the via layer VIA, the first interlayer insulating layer IL1, and a buffer layer BL. The first electrode RME1 may serve as a first source electrode S1 of the first transistor T1, and the first transistor T1 may be electrically connected to the bottom metal layer BML through the first electrode RME1.

A second electrode RME2 may contact a second voltage wiring VL2 of the first conductive layer through a second electrode contact hole CTS penetrating a second wall BP2, the via layer VIA, the first interlayer insulating layer IL1, and the buffer layer BL. The first electrode RME1 may be electrically connected to the first transistor T1 to receive a first power supply voltage, and the second electrode RME2 may be electrically connected to the second voltage wiring VL2 to receive a second power supply voltage.

The electrode patterns RMP1 through RMP3 may be disposed on a wall layer BPL including the first wall BP1 and the second wall BP2 and may directly contact the first conductive layer, the second conductive layer, or the semiconductor layer under them. For example, the electrode patterns RMP1 through RMP3 may include a first electrode pattern RMP1 electrically connected to a first gate electrode G1 of the first transistor T1 and a second active layer ACT2 of a second transistor T2, a second electrode pattern RMP2 electrically connected to the first active layer ACT1 of the first transistor T1 and a first voltage wiring VL1, and a third electrode pattern RMP3 electrically connected to the second active layer ACT2 of the second transistor T2 and a data line DTL.

The first electrode pattern RMP1 may contact the first gate electrode G1 and the second active layer ACT2 through first contact holes CNT1 penetrating the wall layer BPL, the via layer VIA, and the first interlayer insulating layer IL1. The first electrode pattern RMP1 may serve as a second source electrode S2 of the second transistor T2. The first transistor T1 and the second transistor T2 may be electrically connected to each other through the first electrode pattern RMP1.

The second electrode pattern RMP2 may contact the first active layer ACT1 through a second contact hole CNT2 penetrating the wall layer BPL, the via layer VIA, and the first interlayer insulating layer IL1 and may contact the first voltage wiring VL1 through a second contact hole CNT2 penetrating the wall layer BPL, the via layer VIA, the first interlayer insulating layer IL1 and the buffer layer BL. The second electrode pattern RMP2 may serve as a first drain electrode D1 of the first transistor T1. The first transistor T1 and the first voltage wiring VL1 may be electrically connected to each other through the second electrode pattern RMP2.

The third electrode pattern RMP3 may contact the second active layer ACT2 and the data line DTL through third contact holes CNT3 penetrating the wall layer BPL, the via layer VIA, and the first interlayer insulating layer IL1. The third electrode pattern RMP3 may serve as a second drain electrode D2 of the second transistor T2. The second transistor T2 and the data line DTL may be electrically connected to each other through the third electrode pattern RMP3.

In a display device according to one or more embodiments, an electrode may include metal layers including different materials, and each of the metal layers may have a specific thickness and a small taper angle. Accordingly, in the display device, an insulating layer disposed on the electrode may have a uniform film quality without defects, and damage to the electrode through defects during a manufacturing process may be prevented.

However, the effects, aspects, and features of embodiments of the present disclosure are not restricted to the one set forth herein. The above and other effects, aspects, and features of the present disclosure will become more apparent to one of daily skill in the art to which the present disclosure pertains by referencing the claims.

In concluding the detailed description, those skilled in the art will appreciate that many variations and modifications can be made to the described embodiments without substantially departing from the principles and scope of the present disclosure. Therefore, the disclosed embodiments of the present disclosure are used in a generic and descriptive sense only and not for purposes of limitation.

What is claimed is:

1. A display device comprising:
a first electrode and a second electrode spaced from the first electrode;
a first insulating layer on the first electrode and the second electrode;
a plurality of light emitting elements on the first insulating layer and on the first electrode and the second electrode;
a first connection electrode on the first electrode and contacting the plurality of light emitting elements; and
a second connection electrode on the second electrode and contacting the plurality of light emitting elements,
wherein each of the first electrode and the second electrode comprises a first metal layer and a second metal layer on the first metal layer and comprising a different material from the first metal layer,
wherein a thickness of the first metal layer is between 100 Å to 300 Å, and
wherein a thickness of each of the first electrode and the second electrode is 2600 Å or less.

2. The display device of claim 1, wherein the first electrode and the second electrode have a taper angle of 25 degrees or less.

3. The display device of claim 2, wherein the first metal layer and the second metal layer have a same taper angle.

4. The display device of claim 2, wherein a taper angle of the first metal layer is greater than a taper angle of the second metal layer.

5. The display device of claim 1, wherein the first metal layer comprises molybdenum (Mo), and the second metal layer is comprises an alloy comprising aluminum (Al), nickel (Ni), and lanthanum (La).

6. The display device of claim 1, wherein a width of the first metal layer is greater than a width of the second metal layer, and
wherein an end of a lower surface of the second metal layer is recessed inward from an end of an upper surface of the first metal layer.

7. The display device of claim 1, further comprising a second insulating layer on the plurality of light emitting elements,
wherein the first connection electrode and the second connection electrode are on the second insulating layer.

8. The display device of claim 7, wherein the first connection electrode and the second connection electrode contact side surfaces of a portion of the second insulating layer on the plurality of light emitting elements.

9. The display device of claim 7, further comprising a third insulating layer on the second insulating layer and the second connection electrode,
wherein the first connection electrode is on the third insulating layer.

10. The display device of claim 1, further comprising:
a first wall overlapping the first electrode and a second wall overlapping the second electrode; and
a bank layer around an area of the display device in which the plurality of light emitting elements are located,
wherein the plurality of light emitting elements is between the first wall and the second wall.

11. The display device of claim 10, wherein the first electrode is on the first wall, and the second electrode is directly on the second wall.

12. The display device of claim 10, wherein each of the first wall and the second wall is on the first insulating layer,
the first connection electrode is on the first wall, and
the second connection electrode is on the second wall.

13. The display device of claim 1, comprising:
a first conductive layer comprising a bottom metal layer, a first voltage wiring and a second voltage wiring on a substrate on which the first electrode and the second electrode are located;
a buffer layer on the first conductive layer;
a first active layer and a second active layer on the buffer layer;
a first gate insulating layer on the first active layer and the second active layer;
a second conductive layer on the first gate insulating layer and comprising a first gate electrode overlapping the first active layer and a second gate electrode overlapping the second active layer;
a first interlayer insulating layer on the second conductive layer;
a third conductive layer on the first interlayer insulating layer and comprising a first conductive pattern contacting the bottom metal layer and the first active layer, a second conductive pattern contacting the second voltage wiring, and a third conductive pattern contacting the first active layer and the first voltage wiring; and
a via layer on the third conductive layer,
wherein the first electrode is on the via layer to contact the first conductive pattern, and
wherein the second electrode is on the via layer to contact the second conductive pattern.

14. The display device of claim 1, comprising:
a first conductive layer comprising a bottom metal layer, a first voltage wiring, and a second voltage wiring on a substrate on which the first electrode and the second electrode are located;
a buffer layer on the first conductive layer;
a first active layer and a second active layer on the buffer layer;
a first gate insulating layer on the first active layer and the second active layer;
a second conductive layer on the first gate insulating layer and comprising a first gate electrode overlapping the first active layer and a second gate electrode overlapping the second active layer;
a first interlayer insulating layer on the second conductive layer; and
a via layer on the first interlayer insulating layer,
wherein the first electrode is on the via layer to contact the first active layer and the bottom metal layer, and
wherein the second electrode is on the via layer to contact the second voltage wiring.

15. A display device comprising:
a first electrode and a second electrode spaced from the first electrode;
a first wall overlapping the first electrode and a second wall overlapping the second electrode;
a first insulating layer on the first electrode and the second electrode;
a plurality of light emitting elements on the first insulating layer and on the first electrode and the second electrode, the plurality of light emitting elements being located between the first wall and the second wall;
a first connection electrode on the first electrode and contacting the plurality of light emitting elements; and
a second connection electrode on the second electrode and contacting the plurality of light emitting elements,
wherein each of the first electrode and the second electrode comprises a first metal layer and a second metal layer on the first metal layer and comprising a different material from the first metal layer, and
wherein the first electrode and the second electrode have a taper angle of 25 degrees or less.

16. The display device of claim 15, wherein the first metal layer and the second metal layer have a same taper angle.

17. The display device of claim 15, wherein a taper angle of the first metal layer is greater than a taper angle of the second metal layer.

18. The display device of claim 15, wherein a thickness of the first metal layer is between 100 Å to 300 Å, and
wherein a thickness of each of the first electrode and the second electrode is 2600 Å or less.

19. The display device of claim 15, wherein the first metal layer comprises molybdenum (Mo), and the second metal layer comprises an alloy comprising aluminum (Al), nickel (Ni) and lanthanum (La).

20. The display device of claim 15, further comprising:
a second insulating layer on the plurality of light emitting elements; and
a third insulating layer on the second insulating layer and the second connection electrode,
wherein the first connection electrode is on the third insulating layer.
